(19) United States
(12) Patent Application Publication
(10) Pub. No.: US 2023/0316693 A1
(43) Pub. Date: Oct. 5, 2023

(54) SOLID-STATE IMAGING DEVICE AND RECOGNITION SYSTEM

(71) Applicant: SONY GROUP CORPORATION, Tokyo (JP)

(72) Inventor: Kei NAKAGAWA, Tokyo (JP)

(73) Assignee: SONY GROUP CORPORATION, Tokyo (JP)

(21) Appl. No.: 18/043,956

(22) PCT Filed: Sep. 3, 2021
(86) PCT No.: PCT/JP2021/032405

§ 371 Date: Mar. 3, 2023

(30) Foreign Application Priority Data
Sep. 16, 2020 (JP) 2020-155690

(51) Int. Cl. G06V 10/147; H10K 39/32; H04N 25/47; H04N 25/78; H04N 25/79; H04N 23/11; H04N 23/80; H04N 23/74; G06V 10/143

(52) U.S. Cl. CPC G06V 10/147; H10K 39/32; H04N 25/47; H04N 25/78; H04N 25/79; H04N 23/11; H04N 23/80; H04N 23/74; G06V 10/143; G06V 40/172

(57) ABSTRACT

More secure authentication is enabled. A solid-state imaging device according to an embodiment includes: an image processing unit that includes a plurality of first pixels arranged in a matrix on a first surface and generates image data on the basis of a light amount of incident light incident on each of the first pixels; and an event signal processing unit that includes a plurality of second pixels arranged in a matrix on a second surface parallel to the first surface and generates event data on the basis of a luminance change of incident light incident on each of the second pixels, in which the plurality of first pixels and the plurality of second pixels are arranged on a single chip.

### FIELD

The present disclosure relates to a solid-state imaging device and a recognition system.

### BACKGROUND

In recent years, with the spread of portable devices such as smartphones and tablet terminals, secure authentication systems have been required.

### CITATION LIST

### Patent Literature

Patent Literature 1: JP 2020-21855 A

Patent Literature 2: JP 2018-125848 A

### SUMMARY

### Technical Problem

However, conventionally, since an authentication system based on information acquired by one sensor is common, there is room for improvement in security against unauthorized access such as impersonation.

Therefore, the present disclosure proposes a solid-state imaging device and a recognition system that enable more secure authentication.

### Solution to Problem

To solve the problems described above, a solid-state imaging device according to an embodiment of the present disclosure includes: an image processing unit including a plurality of first pixels arranged in a matrix on a first surface, the image processing unit generating image data based on a light amount of incident light incident on each of the first pixels; and an event signal processing unit including a plurality of second pixels arranged in a matrix on a second surface parallel to the first surface, the event signal processing unit generating event data based on a luminance change of incident light incident on each of the second pixels, wherein the plurality of first pixels and the plurality of second pixels are arranged on a single chip.

### BRIEF DESCRIPTION OF DRAWINGS

FIG. 1 is a block diagram illustrating a functional configuration example of a recognition system according to a first embodiment.

FIG. 2 is a schematic diagram illustrating a schematic configuration example of an electronic device that implements the recognition system according to the first embodiment.

FIG. 3 is a block diagram illustrating a schematic configuration example of an electronic device that implements the recognition system according to the first embodiment.

FIG. 4 is a block diagram illustrating a schematic configuration example of an image sensor according to the first embodiment.

FIG. 5 is a schematic diagram illustrating a schematic configuration example of a pixel array unit according to the first embodiment.

FIG. 6 is a circuit diagram illustrating a schematic configuration example of a unit pixel according to the first embodiment.

FIG. 7 is a circuit diagram illustrating a schematic configuration example of a unit pixel according to a modification example of the first embodiment.

FIG. 8 is a cross-sectional view illustrating a cross-sectional structure example of the image sensor according to the first embodiment.

FIG. 9 is a diagram illustrating a planar layout example of each layer of the pixel array unit according to the first embodiment.

FIG. 10 is a plan view illustrating an example of wiring of pixel drive lines for RGB pixels according to the first embodiment.

FIG. 11 is a plan view illustrating an example of wiring of pixel drive lines for EVS pixels according to the first embodiment.

FIG. 12 is a plan view illustrating an example of wiring of signal lines for the EVS pixels according to the first embodiment.

FIG. 13 is a diagram illustrating a laminated structure example of the image sensor according to the first embodiment.

FIG. 14 is a flowchart illustrating an example of a recognition operation according to the first embodiment.

FIG. 15 is a circuit diagram illustrating an EVS pixel according to a first circuit configuration example of the first embodiment.

FIG. 16 is a circuit diagram illustrating an EVS pixel according to a second circuit configuration example of the first embodiment.

FIG. 17 is a circuit diagram illustrating an EVS pixel according to a third circuit configuration example of the first embodiment.

FIG. 18 is a circuit diagram illustrating an EVS pixel according to a fourth circuit configuration example of the first embodiment.

FIG. 19 is a flowchart illustrating processing of synchronization control according to a first example of the first embodiment.

FIG. 20 is a flowchart illustrating processing of synchronization control according to a second example of the first embodiment.

FIG. 21 is a flowchart illustrating processing of synchronization control according to a third example of the first embodiment.

FIG. 22 is a flowchart illustrating processing of synchronization control according to a fourth example of the first embodiment.

FIG. 23 is a diagram illustrating a pixel arrangement example (part 1) of ON pixels and OFF pixels according to a fifth example of the first embodiment.

FIG. 24 is a diagram illustrating another pixel arrangement example (part 1) of ON pixels and OFF pixels according to the fifth example of the first embodiment.

FIG. 25 is a diagram illustrating a pixel arrangement example (part 2) of ON pixels and OFF pixels according to the fifth example of the first embodiment.

FIG. 26 is a diagram illustrating another pixel arrangement example (part 2) of ON pixels and OFF pixels according to the fifth example of the first embodiment.

FIG. 27 is a flowchart illustrating processing of synchronization control according to a sixth example of the first embodiment.

FIG. 28 is a flowchart illustrating processing of synchronization control according to a seventh example of the first embodiment.

FIG. 29 is a schematic diagram illustrating a schematic configuration example of a unit pixel according to a second embodiment.

FIG. 30 is a circuit diagram illustrating a schematic configuration example of a unit pixel according to the second embodiment.

FIG. 31 is a cross-sectional view illustrating a cross-sectional structure example of an image sensor according to the second embodiment.

FIG. 32 is a diagram illustrating a planar layout example of each layer of a pixel array unit according to the second embodiment.

FIG. 33 is a diagram illustrating a planar layout example of each layer of a pixel array unit according to a modification example of an on-chip lens of the second embodiment.

FIG. 34 is a diagram illustrating a planar layout example of each layer of a pixel array unit according to a modification example of a color filter array of the second embodiment.

FIG. 35 is an external view of a smartphone according to a specific example of an electronic device of the present disclosure as viewed from a front side.

FIG. 36 is a block diagram depicting an example of schematic configuration of a vehicle control system.

FIG. 37 is a diagram of assistance in explaining an example of installation positions of an outside-vehicle information detecting section and an imaging section.

### DESCRIPTION OF EMBODIMENTS

Hereinafter, embodiments of the present disclosure will be described in detail with reference to the drawings. Note that, in each of the following embodiments, the same parts are denoted by the same reference signs, and redundant description will be omitted.

In addition, the present disclosure will be described according to the following item order.

1. First embodiment

1.1 Functional configuration example of recognition system

1.2 System configuration example

1.3 Configuration example of image sensor

1.4 Configuration example of unit pixel

1.5 Example of circuit configuration of unit pixel

1.5.1 Modification example of circuit configuration

1.6 Cross-sectional structure example of unit pixel

1.7 Organic material

1.8 Planar structure example

1.9 Wiring example of pixel drive line

1.10 Laminated structure example of image sensor

1.11 Recognition operation example

1.12 Example of circuit configuration of EVS pixel

1.12.1 First circuit configuration example

1.12.2 Second circuit configuration example

1.12.3 Third circuit configuration example

1.12.4 Fourth circuit configuration example

1.13 Synchronization control between laser light source and image sensor

1.13.1 First example

1.13.2 Second example

1.13.3 Third example

1.13.4 Fourth example

1.13.5 Fifth example

1.13.6 Sixth example

1.13.7 Seventh example

1.14 Working and effect

2. Second embodiment

2.1 Configuration example of unit pixel

2.2 Example of circuit configuration of unit pixel

2.3 Cross-sectional structure example of unit pixel

2.4 Planar structure example

2.5 Modification example of on-chip lens

2.6 Modification example of color filter array

2.7 Working and effect

3. Specific example of electronic device

4. Application example to mobile body

### 1. First Embodiment

First, a solid-state imaging device (Hereinafter, referred to as an image sensor.), an electronic device, and a recognition system according to a first embodiment will be described in detail with reference to the drawings. Note that, in the present embodiment, a case where a technique according to the present embodiment is applied to a complementary metal-oxide semiconductor (CMOS) image sensor will be exemplified, but the present invention is not limited thereto. For example, the technique according to the present embodiment can be applied to various sensors including a photoelectric conversion element, such as a charge-coupled device (CCD) image sensor and a time-of-flight (ToF) sensor.

1.1 Functional Configuration Example of Recognition System

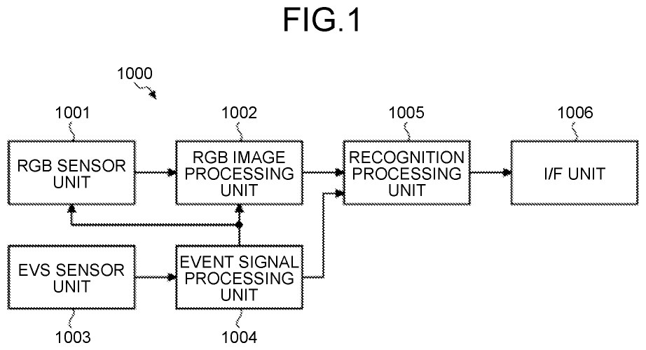

FIG. 1 is a block diagram illustrating a functional configuration example of a recognition system according to a first embodiment. As illustrated in FIG. 1, a recognition system 1000 includes two types of sensor units, an RGB sensor unit 1001 and an EVS sensor unit 1003. Furthermore, the recognition system 1000 includes an RGB image processing unit 1002, an event signal processing unit 1004, a recognition processing unit 1005, and an interface (I/F) unit 1006. The RGB image processing unit 1002 may include the RGB sensor unit 1001, and the event signal processing unit 1004 may include the EVS sensor unit 1003.

The RGB sensor unit 1001 includes, for example, a plurality of pixels (Hereinafter, referred to as RGB pixels.) including a color filter that transmits wavelength components of each of the three primary colors of RGB, and generates a color image (Hereinafter, referred to as an RGB image.) including color components of the three primary colors of RGB. Note that, instead of the RGB sensor unit 1001, a sensor unit or the like including a plurality of pixels including a color filter that transmits wavelength components of each of the three CMY primary colors may be used.

The EVS sensor unit 1003 includes, for example, a plurality of pixels (Hereinafter, referred to as an EVS pixels.) including an IR filter that transmits infrared (IR) light, and outputs event data (Also referred to as event information or a detection signal.) indicating a position (Hereinafter, referred to as an address.) of a pixel where an event has been detected on the basis of whether or not each EVS pixel has detected IR light (Hereinafter, referred to as an event.). Note that, in the present embodiment, the event may include an on-event indicating that IR light has come to be detected and an off-event indicating that IR light is desired to be detected.

The RGB image processing unit 1002 executes predetermined signal processing such as noise removal, white balance adjustment, and pixel interpolation on RGB image data input from the RGB sensor unit 1001. Furthermore, the RGB image processing unit 1002 may execute recognition processing or the like using the RGB image data.

On the basis of event data input from the EVS sensor unit 1003, the event signal processing unit 1004 generates image data (Hereinafter, referred to as EVS image data.) indicating pixels in which an event has been detected. For example, the event signal processing unit 1004 generates EVS image data indicating a pixel in which an on-event and/or an off-event is detected on the basis of event data input within a predetermined period. Note that the event signal processing unit 1004 may generate the EVS image data using an address of the pixel in which the event is detected, or may generate the EVS image data using a gradation signal (pixel signal) indicating the luminance of incident light read from the pixel in which the event is detected. Furthermore, the event signal processing unit 1004 may execute predetermined signal processing such as noise removal on the generated EVS image data.

Using the RGB image data input from the RGB image processing unit 1002 and/or the EVS image data input from the event signal processing unit 1004, the recognition processing unit 1005 executes recognition processing of an object or the like existing within an angle of view of the RGB sensor unit 1001 and/or the EVS sensor unit 1003. For the recognition processing by the recognition processing unit 1005, recognition processing such as pattern recognition, recognition processing by artificial intelligence (AI), or the like may be used. For example, deep learning using a neural network such as convolution neural network (CNN) or recurrent neural network (RNN) may be applied to the recognition processing by AI. Furthermore, the recognition processing unit 1005 may execute part of the recognition processing and output a result (intermediate data or the like) thereof.

The interface unit 1006 outputs a recognition result (including intermediate data and the like) obtained by the recognition processing unit 1005 and image data acquired by the RGB sensor unit 1001 and/or the EVS sensor unit 1003 to an external application processor 1100, for example.

Note that the event signal processing unit 1004 may execute region determination of an object on the EVS image data, and input information (Hereinafter, it is simply referred to as ROI information.) such as an address specifying a region of interest (ROI) obtained as a result to the RGB sensor unit 1001 and/or the RGB image processing unit 1002. On the other hand, the RGB sensor unit 1001 may operate to acquire the RGB image data of the region corresponding to the ROI information input from the event signal processing unit 1004. Alternatively, the RGB image processing unit 1002 may perform processing such as trimming of a region corresponding to the ROI information input from the event signal processing unit 1004 on the RGB image data input from the RGB sensor unit 1001.

1.2 System Configuration Example

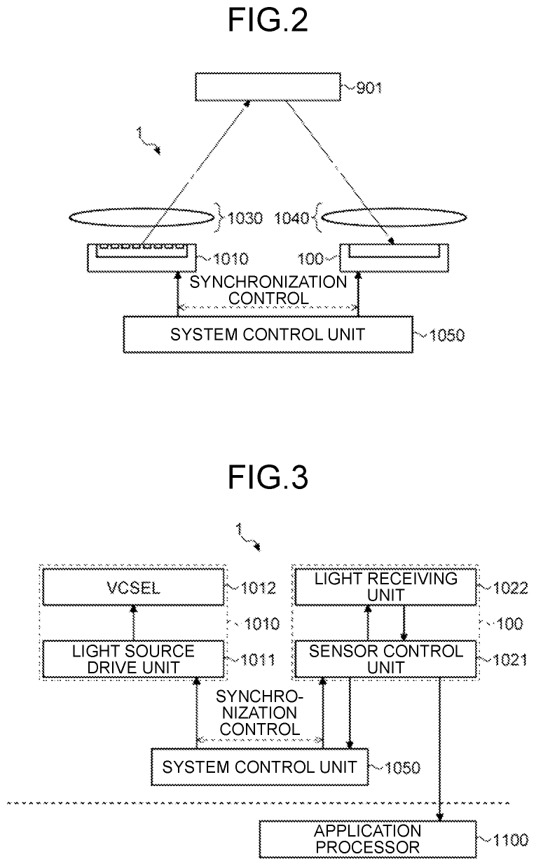

Next, a system configuration example of the recognition system according to the present embodiment will be described. FIG. 2 is a schematic diagram illustrating a schematic configuration example of an electronic device that implements the recognition system according to the first embodiment, and FIG. 3 is a block diagram illustrating a schematic configuration example of an electronic device that implements the recognition system according to the first embodiment.

As illustrated in FIG. 2, an electronic device 1 according to the present embodiment includes a laser light source 1010, an irradiation lens 1030, an imaging lens 1040, an image sensor 100, and a system control unit 1050.

As illustrated in FIG. 3, the laser light source 1010 includes, for example, a vertical cavity surface emitting laser (VCSEL) 1012 and a light source drive unit 1011 that drives the VCSEL 1012. However, the present invention is not limited to the VCSEL 1012, and various light sources such as a light emitting diode (LED) may be used. Furthermore, the laser light source 1010 may be any of a point light source, a surface light source, and a line light source. In the case of a surface light source or a line light source, the laser light source 1010 may have, for example, a configuration in which a plurality of point light sources (for example, VCSELs) is arranged one-dimensionally or two-dimensionally. Note that, in the present embodiment, the laser light source 1010 may emit light of a wavelength band different from a wavelength band of visible light, such as infrared (IR) light, for example.

The irradiation lens 1030 is disposed on an emission surface side of the laser light source 1010, and converts light emitted from the laser light source 1010 into irradiation light having a predetermined divergence angle.

The imaging lens 1040 is disposed on a light receiving surface side of the image sensor 100, and forms an image by incident light on the light receiving surface of the image sensor 100. The incident light can also include reflected light emitted from the laser light source 1010 and reflected by a subject 901.

As will be described in detail later, as illustrated in FIG. 3, the image sensor 100 includes, for example, a light receiving unit 1022 in which RGB pixels and EVS pixels are arranged in a two-dimensional lattice, and a sensor control unit 1021 that drives the light receiving unit 1022 to generate RGB image data and event data.

The system control unit 1050 includes, for example, a processor (CPU), and drives the VCSEL 1012 via the light source drive unit 1011. Furthermore, the system control unit 1050 controls the image sensor 100 to acquire an RGB image, and controls the image sensor 100 in synchronization with the control on the laser light source 1010 to acquire event data detected according to light emission/extinction of the laser light source 1010.

In such a configuration, the RGB sensor unit 1001 in FIG. 1 may be configured using the image sensor 100 and the system control unit 1050, and the EVS sensor unit 1003 may be configured using the laser light source 1010, the image sensor 100, and the system control unit 1050. Furthermore, the RGB image processing unit 1002, the event signal processing unit 1004, and the recognition processing unit 1005 in FIG. 1 may be configured using the image sensor 100 and/or the application processor 1100, respectively.

For example, irradiation light emitted from the laser light source 1010 is projected onto the subject (also referred to as a measurement target or an object) 901 through the irradiation lens 1030. The projected light is reflected by the subject 901. Then, the light reflected by the subject 901 is incident on the image sensor 100 through the imaging lens 1040. The EVS sensor unit 1003 in the image sensor 100 receives the reflected light reflected by the subject 901 to generate event data, and generates EVS image data on the basis of the generated event data. On the other hand, the RGB sensor unit 1001 in the image sensor 100 receives, for example, visible light in the incident light and generates RGB image data. The RGB image data and the EVS image data generated by the image sensor 100 are supplied to the application processor 1100 of the electronic device 1. The application processor 1100 executes predetermined processing such as recognition processing on the RGB image data and the EVS image data input from the image sensor 100.

1.3 Configuration Example of Image Sensor

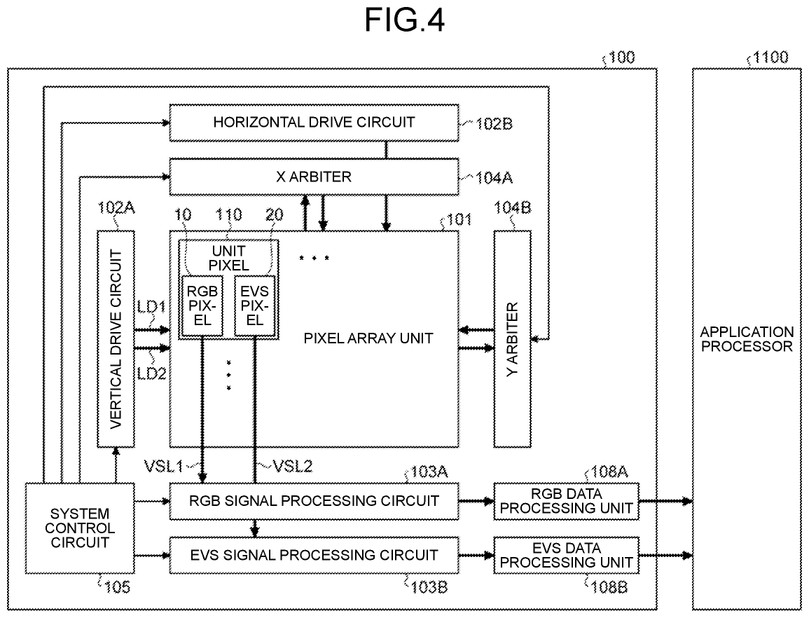

FIG. 4 is a block diagram illustrating a schematic configuration example of the image sensor according to the first embodiment. As illustrated in FIG. 4, the image sensor 100 according to the present embodiment includes, for example, a pixel array unit 101, a vertical drive circuit 102A, a horizontal drive circuit 102B, an X arbiter 104A, a Y arbiter 104B, an RGB signal processing circuit 103A, an EVS signal processing circuit 103B, a system control circuit 105, an RGB data processing unit 108A, and an EVS data processing unit 108B.

The pixel array unit 101, the vertical drive circuit 102A, the horizontal drive circuit 102B, the RGB signal processing circuit 103A, and the system control circuit 105 constitute, for example, the RGB sensor unit 1001 in FIG. 1, and the pixel array unit 101, the vertical drive circuit 102A, the horizontal drive circuit 102B, the X arbiter 104A, the Y arbiter 104B, the EVS signal processing circuit 103B, the horizontal drive circuit 102B, and the system control circuit 105 constitute, for example, the EVS sensor unit 1003 in FIG. 1. Furthermore, the RGB signal processing circuit 103A and the RGB data processing unit 108A constitute, for example, the RGB image processing unit 1002 in FIG. 1, and the EVS signal processing circuit 103B and the EVS data processing unit 108B constitute, for example, the event signal processing unit 1004 in FIG. 1. Note that the recognition processing unit 1005 in FIG. 1 may be realized by the application processor 1100 alone, may be realized by causing the RGB data processing unit 108A and the EVS data processing unit 108B to cooperate with the application processor 1100, or may be realized by causing the RGB data processing unit 108A and the EVS data processing unit 108B to cooperate with each other.

The pixel array unit 101 has a configuration in which unit pixels 110 are arranged in the row direction and the column direction, that is, in a two-dimensional lattice shape (also referred to as a matrix shape). Here, the row direction refers to an arrangement direction of pixels in a pixel row (lateral direction in drawings), and the column direction refers to an arrangement direction of pixels in a pixel column (longitudinal direction in drawings).

Each unit pixel 110 includes an RGB pixel 10 and an EVS pixel 20. In the present description, the RGB pixel 10 and the EVS pixel 20 may be simply referred to as pixels, respectively. Although details of a specific circuit configuration and a pixel structure of the unit pixel 110 will be described later, the RGB pixel 10 includes a photoelectric conversion element that generates and accumulates charges according to the amount of received light, and generates a pixel signal of a voltage according to the amount of incident light. On the other hand, similarly to the RGB pixel 10, the EVS pixel 20 includes a photoelectric conversion element that generates and accumulates a charge corresponding to the amount of received light, and when detecting incidence of light on the basis of the photocurrent flowing out of the photoelectric conversion element, outputs a request for requesting reading from itself to the X arbiter 104A and the Y arbiter 104B, and outputs a signal (also referred to as event data) indicating that an event has been detected according to arbitration by the X arbiter 104A and the Y arbiter 104B. A time stamp indicating the time when the event is detected may be added to the event data.

In the pixel array unit 101, the pixel drive lines LD1 and LD2 are wired along the row direction for each pixel row, and the vertical signal lines VSL1 and VSL2 are wired along the column direction for each pixel column with respect to the matrix-like pixel array. For example, the pixel drive line LD1 is connected to the RGB pixels 10 in each row, and the pixel drive line LD2 is connected to the EVS pixels 20 in each row. On the other hand, for example, the vertical signal line VSL1 is connected to the RGB pixels 10 of each column, and the vertical signal line VSL2 is connected to the EVS pixels 20 of each column. However, the present invention is not limited thereto, and the pixel drive lines LD1 and LD2 may be wired so as to be orthogonal to each other. Similarly, the vertical signal lines VSL1 and VSL2 may be wired so as to be orthogonal to each other. For example, the pixel drive line LD1 may be wired in the row direction, the pixel drive line LD2 may be wired in the column direction, the vertical signal line VSL1 may be wired in the column direction, and the vertical signal line VSL2 may be wired in the row direction.

The pixel drive line LD1 transmits a control signal for performing driving when a pixel signal is read from the RGB pixel 10. The pixel drive line LD2 transmits a control signal for bringing the EVS pixel 20 into an active state in which an event can be detected. In FIG. 4, each of the pixel drive lines LD1 and LD2 is illustrated as one wiring, but the number is not limited to one. One end of each of the pixel drive line LD1 and the pixel drive line LD2 is connected to an output end corresponding to each row of the vertical drive circuit 102A.

(Drive Configuration of RGB Pixels)

As will be described in detail later, each of the RGB pixels 10 includes a photoelectric conversion unit that photoelectrically converts incident light to generate a charge, and a pixel circuit that generates a pixel signal having a voltage value corresponding to the charge amount of the charge generated in the photoelectric conversion unit, and causes the pixel signal to appear in the vertical signal line VSL1 under the control of the vertical drive circuit 102A.

The vertical drive circuit 102A includes a shift register, an address decoder, and the like, and drives the RGB pixels 10 of the pixel array unit 101 at the same time for all pixels or in units of rows. That is, the vertical drive circuit 102A constitutes a drive unit that controls the operation of each of the RGB pixels 10 of the pixel array unit 101 together with the system control circuit 105 that controls the vertical drive circuit 102A. Although a specific configuration of the vertical drive circuit 102A is not illustrated, the vertical drive circuit generally includes two scanning systems of a reading scanning system and a sweeping scanning system.

The readout scanning system sequentially selects and scans each pixel of the pixel array unit 101 row by row in order to read out a signal from each pixel. The pixel signal read from each pixel is an analog signal. The sweep scanning system performs sweep scanning on a read row on which read scanning is performed by the read scanning system prior to the read scanning by an exposure time.

By the sweep scanning by the sweep scanning system, unnecessary charges are swept out from the photoelectric conversion element of each pixel of the read row, whereby the photoelectric conversion element is reset. Then, by sweeping out (resetting) unnecessary charges in the sweeping scanning system, a so-called electronic shutter operation is performed. Here, the electronic shutter operation refers to an operation of discarding charges of the photoelectric conversion element and newly starting exposure (starting accumulation of charges).

The signal read by the read operation by the read scanning system corresponds to the amount of light received after the immediately preceding read operation or electronic shutter operation. Then, a period from the read timing by the immediately preceding read operation or the sweep timing by the electronic shutter operation to the read timing by the current read operation is a charge accumulation period (also referred to as an exposure period) in each pixel.

The pixel signal output from each of the RGB pixels 10 of the pixel row selectively scanned by the vertical drive circuit 102A is input to the RGB signal processing circuit 103A through each of the vertical signal lines VSL1 for each pixel column. The RGB signal processing circuit 103A performs predetermined signal processing on the pixel signal output from each of the RGB pixels 10 of the selected row through the vertical signal line VSL1 for each pixel column of the pixel array unit 101, and temporarily holds the pixel signal after the signal processing.

Specifically, the RGB signal processing circuit 103A performs at least noise removal processing such as correlated double sampling (CDS) processing or double data sampling (DDS) processing as signal processing. For example, the fixed pattern noise unique to the pixel such as the reset noise and the threshold variation of the amplification transistor in the pixel is removed by the CDS processing. The RGB signal processing circuit 103A also has, for example, an analog-digital (AD) conversion function, converts an analog pixel signal read from the photoelectric conversion element into a digital signal, and outputs the digital signal.

The horizontal drive circuit 102B includes a shift register, an address decoder, and the like, and sequentially selects a readout circuit (Hereinafter, referred to as a pixel circuit.) corresponding to a pixel column of the RGB signal processing circuit 103A. By the selective scanning by the horizontal drive circuit 102B, pixel signals subjected to signal processing for each pixel circuit in the RGB signal processing circuit 103A are sequentially output.

(Drive Configuration of EVS Pixel)

Each EVS pixel 20 detects the presence or absence of an event based on whether or not a change exceeding a predetermined threshold has occurred in the photocurrent according to the luminance of the incident light. For example, each EVS pixel 20 detects that the luminance change exceeds or falls below a predetermined threshold as an event.

When detecting an event, the EVS pixel 20 outputs a request for requesting permission to output event data indicating the occurrence of the event to each of the X arbiter 104A and the Y arbiter 104B. Then, in a case where the EVS pixel 20 receives a response indicating the permission to output the event data from each of the X arbiter 104A and the Y arbiter 104B, the EVS pixel outputs the event data to the vertical drive circuit 102A and the EVS signal processing circuit 103B.

Furthermore, the EVS pixel 20 that has detected the event outputs an analog pixel signal generated by photoelectric conversion to the EVS signal processing circuit 103B. That is, as a result of the arbitration by the X arbiter 104A and the Y arbiter 104B, the EVS pixel 20 permitted to read requests the vertical drive circuit 102A to drive itself. On the other hand, the vertical drive circuit 102A drives the EVS pixel 20 allowed to be read by arbitration, thereby causing the pixel signal to appear in the vertical signal line VSL2 connected to the EVS pixel 20.

The X arbiter 104A arbitrates a request for requesting the output of the event data supplied from each of the plurality of EVS pixels 20, and transmits a response based on the arbitration result (permission/non-permission of the output of the event data) and a reset signal for resetting the event detection to the EVS pixel 20 that has output the request.

The EVS signal processing circuit 103B has an AD conversion function similarly to the RGB signal processing circuit 103A, and converts an analog pixel signal read from the photoelectric conversion unit into a digital signal and outputs the digital signal. Furthermore, the EVS signal processing circuit 103B may have a noise removal function such as CDS processing or DDS processing, for example, similarly to the RGB signal processing circuit 103A.

In addition, the EVS signal processing circuit 103B performs predetermined signal processing on the digital pixel signal obtained by the AD conversion and the event data input from the EVS pixel 20, and outputs the event data and the pixel signal after the signal processing.

As described above, the change in the photocurrent generated in the EVS pixel 20 can also be regarded as a change in the amount of light (luminance change) incident on the photoelectric conversion unit of the EVS pixel 20. Therefore, it can also be said that the event is a light amount change (luminance change) of the EVS pixel 20 exceeding the predetermined threshold. The event data indicating the occurrence of the event includes at least position information such as coordinates indicating the position of the EVS pixel 20 where the light amount change as the event has occurred. The event data can include the polarity of the light amount change in addition to the position information.

For a series of event data output at the timing when an event occurs from the EVS pixel 20, as long as the interval between pieces of event data is maintained at the time when the event occurs, it can be said that the event data implicitly includes time information indicating a relative time when the event occurs.

However, when the interval between the pieces of event data is not maintained as it is at the time of occurrence of the event due to the event data being stored in the memory or the like, the time information implicitly included in the event data is lost. Therefore, before the interval between the pieces of event data is not maintained as it is at the time of occurrence of the event, the EVS signal processing circuit 103B may include time information indicating a relative time at which the event such as a time stamp has occurred in the event data.

(Other Configurations)

The system control circuit 105 includes a timing generator that generates various timing signals, and the like, and performs drive control of the vertical drive circuit 102A, the horizontal drive circuit 102B, the X arbiter 104A, the Y arbiter 104B, the RGB signal processing circuit 103A, the EVS signal processing circuit 103B, and the like on the basis of various timings generated by the timing generator.

Each of the RGB data processing unit 108A and the EVS data processing unit 108B has at least an arithmetic processing function, and performs various signal processing such as arithmetic processing on the image signal output from the RGB signal processing circuit 103A or the EVS signal processing circuit 103B.

The image data output from the RGB data processing unit 108A or the EVS data processing unit 108B may be subjected to predetermined processing in, for example, the application processor 1100 or the like in the electronic device 1 equipped with the image sensor 100, or may be transmitted to the outside via a predetermined network.

Note that the image sensor 100 may include a storage unit for temporarily holding data necessary for signal processing in the RGB data processing unit 108A and the EVS data processing unit 108B, data processed by any one or more of the RGB signal processing circuit 103A, the EVS signal processing circuit 103B, the RGB data processing unit 108A, and the EVS data processing unit 108B, and the like.

1.4 Configuration Example of Unit Pixel

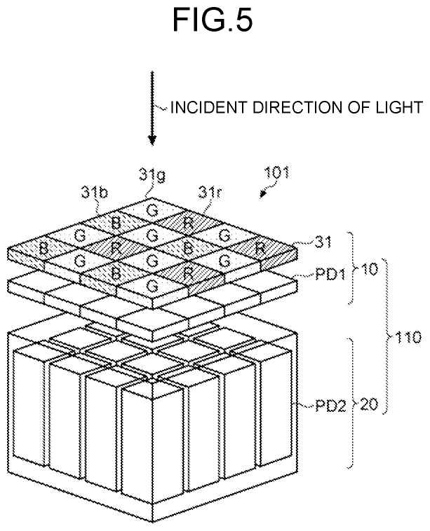

Next, a configuration example of the unit pixel 110 will be described. Note that, here, a case where the unit pixel 110 includes an RGB pixel 10 that acquires an RGB image of three primary colors of RGB and an EVS pixel 20 that detects an event will be described as an example. Note that, in FIG. 5 and the following description, when the color filters 31r, 31g, and 31b that transmit the light of the respective color components constituting the RGB three primary colors are not distinguished, the reference sign is 31.

FIG. 5 is a schematic diagram illustrating a schematic configuration example of the pixel array unit according to the first embodiment. As illustrated in FIG. 5, the pixel array unit 101 has a configuration in which the unit pixels 110 having a structure in which the unit pixels 110 including the RGB pixels 10 and the EVS pixels 20 are arranged along the incident direction of light are arranged in a two-dimensional lattice pattern. That is, in the present embodiment, the RGB pixel 10 and the EVS pixel 20 are positioned in the direction perpendicular to the arrangement direction (plane direction) of the unit pixels 110, and the light transmitted through the RGB pixel 10 positioned on the upstream side in the optical path of the incident light is configured to be incident on the EVS pixel 20 positioned on the downstream side of the RGB pixel 10. According to such a configuration, the photoelectric conversion unit PD2 of the EVS pixel 20 is arranged on the surface side opposite to the incident surface of the incident light in the photoelectric conversion unit PD1 of the RGB pixel 10. Accordingly, in the present embodiment, the optical axes of the incident light of the RGB pixel 10 and the EVS pixel 20 arranged along the incident direction of the light coincide or substantially coincide with each other.

Note that, in the present embodiment, a case where the photoelectric conversion unit PD1 constituting the RGB pixel 10 is made of an organic material and the photoelectric conversion unit PD2 constituting the EVS pixel 20 is made of a semiconductor material such as silicon is exemplified, but the present invention is not limited thereto. For example, both the photoelectric conversion unit PD1 and the photoelectric conversion unit PD2 may be made of a semiconductor material, both the photoelectric conversion unit PD1 and the photoelectric conversion unit PD2 may be made of an organic material, or the photoelectric conversion unit PD1 may be made of a semiconductor material, and the photoelectric conversion unit PD2 may be made of an organic material. Alternatively, at least one of the photoelectric conversion unit PD1 and the photoelectric conversion unit PD2 may be made of a photoelectric conversion material different from the organic material and the semiconductor material.

1.5 Example of Circuit Configuration of Unit Pixel

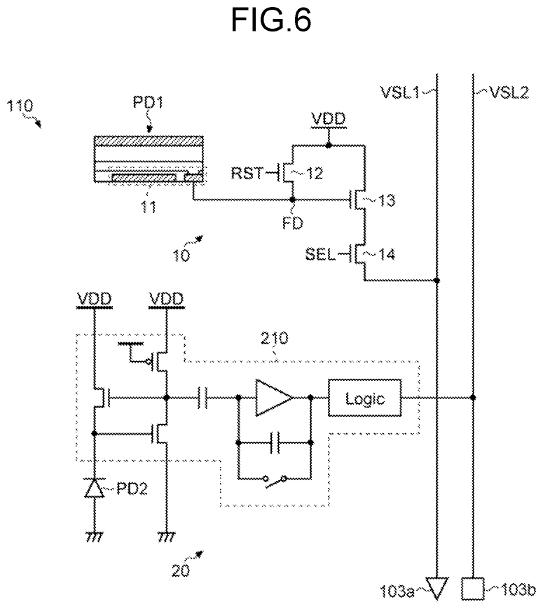

Next, a circuit configuration example of the unit pixel 110 will be described. FIG. 6 is a circuit diagram illustrating a schematic configuration example of a unit pixel according to the first embodiment. As illustrated in FIG. 6, the unit pixel 110 includes one RGB pixel 10 and one EVS pixel 20.

(RGB Pixel 10)

The RGB pixel 10 includes, for example, a photoelectric conversion unit PD1, a transfer gate 11, a floating diffusion region FD, a reset transistor 12, an amplification transistor 13, and a selection transistor 14.

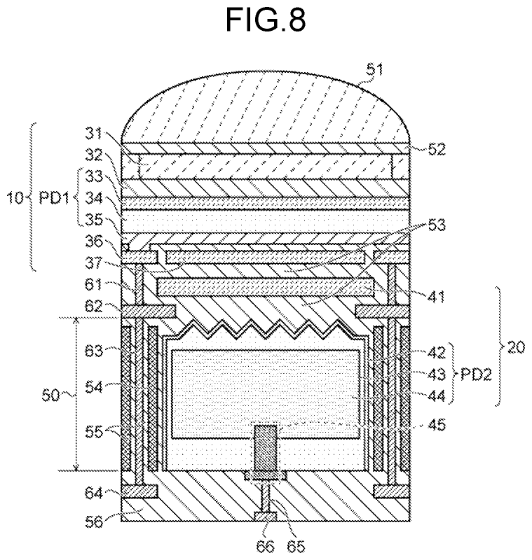

A selection control line included in the pixel drive line LD1 is connected to a gate of the selection transistor 14, a reset control line included in the pixel drive line LD1 is connected to a gate of the reset transistor 12, and a transfer control line included in the pixel drive line LD1 is connected to a storage electrode (see a storage electrode 37 in FIG. 8 described later) described later of the transfer gate 11. Furthermore, the vertical signal line VSL1 having one end connected to the RGB signal processing circuit 103A is connected to the drain of the amplification transistor 13 via the selection transistor 14.

In the following description, the reset transistor 12, the amplification transistor 13, and the selection transistor 14 are also collectively referred to as a pixel circuit. The pixel circuit may include the floating diffusion region FD and/or the transfer gate 11.

The photoelectric conversion unit PD1 is made of, for example, an organic material, and photoelectrically converts incident light. The transfer gate 11 transfers the charge generated in the photoelectric conversion unit PD1. The floating diffusion region FD accumulates the charge transferred by the transfer gate 11. The amplification transistor 13 causes a pixel signal having a voltage value corresponding to the charge accumulated in the floating diffusion region FD to appear in the vertical signal line VSL1. The reset transistor 12 releases the charge accumulated in the floating diffusion region FD. The selection transistor 14 selects the RGB pixel 10 to be read.

The anode of the photoelectric conversion unit PD1 is grounded, and the cathode is connected to the transfer gate 11. The transfer gate 11 will be described later in detail with reference to FIG. 8, and includes, for example, a storage electrode 37 and a read electrode 36. At the time of exposure, a voltage for collecting charges generated in the photoelectric conversion unit PD1 to a semiconductor layer 35 in the vicinity of the storage electrode 37 is applied to the storage electrode 37 via the transfer control line. At the time of reading, a voltage for causing charges collected in the semiconductor layer 35 near the storage electrode 37 to flow out through the read electrode 36 is applied to the storage electrode 37 through the transfer control line.

The charge flowing out through the read electrode 36 is accumulated in the floating diffusion region FD configured by a wiring structure connecting the read electrode 36, the source of the reset transistor 12, and the gate of the amplification transistor 13. Note that the drain of the reset transistor 12 may be connected to, for example, the power supply voltage VDD or a power supply line to which a reset voltage lower than the power supply voltage VDD is supplied.

The source of the amplification transistor 13 may be connected to a power supply line via, for example, a constant current circuit (not illustrated) or the like. The drain of the amplification transistor 13 is connected to the source of the selection transistor 14, and the drain of the selection transistor 14 is connected to the vertical signal line VSL1.

The floating diffusion region FD converts the accumulated charge into a voltage of a voltage value corresponding to the charge amount. Note that the floating diffusion region FD may be, for example, a capacitance-to-ground. However, the floating diffusion region FD is not limited thereto, and may be a capacitance or the like added by intentionally connecting a capacitor or the like to a node where the drain of the transfer gate 11, the source of the reset transistor 12, and the gate of the amplification transistor 13 are connected.

The vertical signal line VSL1 is connected to an analog-to-digital (AD) conversion circuit 103a provided for each column (that is, for each vertical signal line VSL1,) in the RGB signal processing circuit 103A. The AD conversion circuit 103a includes, for example, a comparator and a counter, and converts an analog pixel signal into a digital pixel signal by comparing a reference voltage such as a single slope or a ramp shape input from an external reference voltage generation circuit (digital-to-analog converter (DAC)) with the pixel signal appearing in the vertical signal line VSL1. Note that the AD conversion circuit 103a may include, for example, a correlated double sampling (CDS) circuit and the like, and may be configured to be able to reduce kTC noise and the like.

(EVS Pixel 20)

The EVS pixel 20 includes, for example, a photoelectric conversion unit PD2 and an address event detection circuit 210.

Similarly to the photoelectric conversion unit PD1, the photoelectric conversion unit PD2 is made of, for example, a semiconductor material, and photoelectrically converts incident light. Although the detailed circuit configuration of the address event detection circuit 210 will be described later, as described above, the presence or absence of an event is detected on the basis of the change in the photocurrent flowing out of the photoelectric conversion unit PD2, and when the event is detected, a request for requesting permission to output event data indicating the occurrence of the event is output to each of the X arbiter 104A and the Y arbiter 104B. Then, the address event detection circuit 210 outputs the event data to the vertical drive circuit 102A and the EVS signal processing circuit 103B when receiving the response indicating the output permission of the event data from each of the X arbiter 104A and the Y arbiter 104B. At that time, the address event detection circuit 210 may include time information indicating a relative time at which the event such as a time stamp has occurred in the event data.

Similarly to the vertical signal line VSL1, the vertical signal line VSL2 is connected to a signal processing circuit 103b provided for each column (that is, for each vertical signal line VSL2,) in the EVS signal processing circuit 103B.

1.5.1 Modification Example of Circuit Configuration

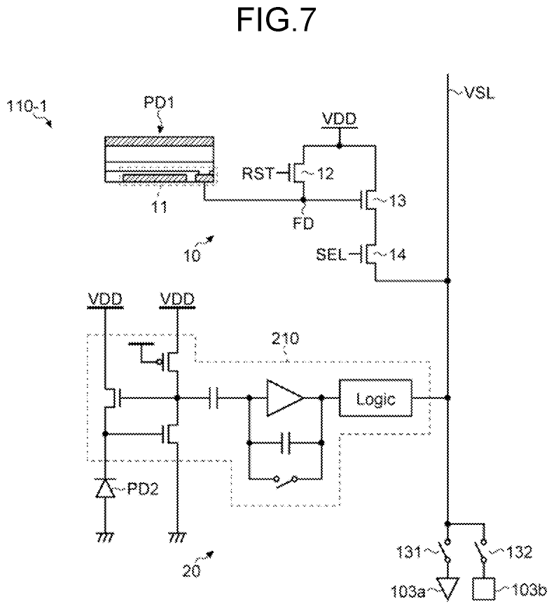

FIG. 7 is a circuit diagram illustrating a schematic configuration example of a unit pixel according to a modification example of the first embodiment. As illustrated in FIG. 7, an unit pixel 110-1 has a structure in which the RGB pixel 10 and the EVS pixel 20 are connected to a common vertical signal line VSL in the same configuration as the unit pixel 110 illustrated in FIG. 6. The vertical signal line VSL is branched in a peripheral circuit, for example, and is connected to the AD conversion circuit 103a of the RGB signal processing circuit 103A or the signal processing circuit 103b of the EVS signal processing circuit 103B via a switch circuit 131 or 132.

For example, the switch circuit 131 may be included in the RGB signal processing circuit 103A or the EVS signal processing circuit 103B. Furthermore, for example, the switch circuit 131 may be provided on the same semiconductor substrate as the pixel circuit of the RGB pixel 10 and/or the EVS pixel 20, may be provided on a semiconductor substrate on which the signal processing circuit is arranged, or may be provided on a semiconductor substrate different from these. Furthermore, the control signal for controlling the switch circuit 131 may be supplied from the vertical drive circuit 102A or the horizontal drive circuit 102B, may be supplied from the sensor control unit 1021 (see FIG. 3), or may be supplied from another configuration.

According to such a configuration, it is possible to reduce the number of vertical signal lines VSL to be wired in the pixel array unit 101, and thereby, it is possible to improve the quantum efficiency by increasing the light receiving area and to reduce the size and resolution of the image sensor 100 by improving the area efficiency.

1.6 Cross-sectional Structure Example of Unit Pixel

Next, an example of a cross-sectional structure of the image sensor 100 according to the first embodiment will be described with reference to FIG. 8. FIG. 8 is a cross-sectional view illustrating a cross-sectional structure example of the image sensor according to the first embodiment. Here, a cross-sectional structure example will be described focusing on a semiconductor chip in which the photoelectric conversion units PD1 and PD2 in the unit pixel 110 are formed.

Furthermore, in the following description, a so-called back surface irradiation type cross-sectional structure in which the light incident surface is on the back surface side (opposite side to the element formation surface) of a semiconductor substrate 50 is exemplified, but the present invention is not limited thereto, and a so-called front surface irradiation type cross-sectional structure in which the light incident surface is on the front surface side (element formation surface side) of the semiconductor substrate 50 may be used. Furthermore, in the present description, a case where an organic material is used for the photoelectric conversion unit PD1 of the RGB pixel 10 is exemplified, but as described above, one or both of an organic material and a semiconductor material (also referred to as an inorganic material) may be used as the photoelectric conversion material of each of the photoelectric conversion units PD1 and PD2.

Note that, in a case where a semiconductor material is used for both the photoelectric conversion material of the photoelectric conversion unit PD1 and the photoelectric conversion material of the photoelectric conversion unit PD2, the image sensor 100 may have a cross-sectional structure in which the photoelectric conversion unit PD1 and the photoelectric conversion unit PD2 are built in the same semiconductor substrate 50, may have a cross-sectional structure in which a semiconductor substrate in which the photoelectric conversion unit PD1 is built and a semiconductor substrate in which the photoelectric conversion unit PD2 is built are bonded, or may have a cross-sectional structure in which one of the photoelectric conversion units PD1 and PD2 is built in the semiconductor substrate 50 and the other is built in a semiconductor layer formed on the back surface or the front surface of the semiconductor substrate 50.

As illustrated in FIG. 8, in the present embodiment, the photoelectric conversion unit PD2 of the EVS pixel 20 is formed on the semiconductor substrate 50, and the photoelectric conversion unit PD1 of the RGB pixel 10 is provided on the back surface side (opposite side to the element formation surface) of the semiconductor substrate 50. In FIG. 8, for convenience of explanation, the back surface of the semiconductor substrate 50 is located on the upper side in the plane of drawing, and the front surface is located on the lower side.

For the semiconductor substrate 50, for example, a semiconductor material such as silicon (Si) may be used. However, the semiconductor material is not limited thereto, and various semiconductor materials including compound semiconductors such as GaAs, InGaAs, InP, AlGaAs, InGaP, AlGaInP, and InGaAsP may be used.

(RGB Pixel 10)

The photoelectric conversion unit PD1 of the RGB pixel 10 is provided on the back surface side of the semiconductor substrate 50 with an insulating layer 53 interposed therebetween. The photoelectric conversion unit PD1 includes, for example, a photoelectric conversion film 34 made of an organic material, and a transparent electrode 33 and a semiconductor layer 35 disposed so as to sandwich the photoelectric conversion film 34. The transparent electrode 33 provided on the upper side (Hereinafter, the upper side in the plane of drawing is an upper surface side, and the lower side is a lower surface side.) in the drawing with respect to the photoelectric conversion film 34 functions as, for example, an anode of the photoelectric conversion unit PD1, and the semiconductor layer 35 provided on the lower surface side functions as a cathode of the photoelectric conversion unit PD1.

The semiconductor layer 35 functioning as a cathode is electrically connected to the read electrode 36 formed in the insulating layer 53. The read electrode 36 is electrically extended to the front surface (lower surface) side of the semiconductor substrate 50 by being connected to wirings 61, 62, 63, and 64 penetrating the insulating layer 53 and the semiconductor substrate 50. Although not illustrated in FIG. 8, the wiring 64 is electrically connected to the floating diffusion region FD illustrated in FIG. 6.

The storage electrode 37 is provided on the lower surface side of the semiconductor layer 35 functioning as a cathode with the insulating layer 53 interposed therebetween. Although not illustrated in FIG. 8, the storage electrode 37 is connected to the transfer control line in the pixel drive line LD1, and as described above, at the time of exposure, a voltage for collecting charges generated in the photoelectric conversion unit PD1 to the semiconductor layer 35 in the vicinity of the storage electrode 37 is applied, and at the time of readout, a voltage for causing charges collected in the semiconductor layer 35 in the vicinity of the storage electrode 37 to flow out via the read electrode 36 is applied.

Similarly to the transparent electrode 33, the read electrode 36 and the storage electrode 37 may be transparent conductive films. For example, a transparent conductive film such as indium tin oxide (ITO) or zinc oxide (IZO) may be used for the transparent electrode 33, the read electrode 36, and the storage electrode 37. However, the present invention is not limited thereto, and various conductive films may be used as long as the photoelectric conversion unit PD2 is a conductive film capable of transmitting light in a wavelength band to be detected.

Furthermore, for the semiconductor layer 35, for example, a transparent semiconductor layer such as IGZO may be used. However, the present invention is not limited thereto, and various semiconductor layers may be used as long as the photoelectric conversion unit PD2 is a semiconductor layer capable of transmitting light in a wavelength band to be detected.

Moreover, as the insulating layer 53, for example, an insulating film such as a silicon oxide film (SiO₂) or a silicon nitride film (SiN) may be used. However, the present invention is not limited thereto, and various insulating films may be used as long as the photoelectric conversion unit PD2 is an insulating film capable of transmitting light in a wavelength band to be detected.

A color filter 31 is provided on the upper surface side of the transparent electrode 33 functioning as an anode with a sealing film 32 interposed therebetween. The sealing film 32 is made of, for example, an insulating material such as silicon nitride (SiN), and may include atoms of aluminum (Al), titanium (Ti), and the like in order to prevent the atoms from diffusing from the transparent electrode 33.

Although the arrangement of the color filters 31 will be described later, for example, a color filter 31 that selectively transmits light of a specific wavelength component is provided for one RGB pixel 10. However, in a case where a monochrome pixel that acquires luminance information is provided instead of the RGB pixel 10 that acquires color information, the color filter 31 may be omitted.

(EVS Pixel 20)

The photoelectric conversion unit PD2 of the EVS pixel 20 includes, for example, a p-type semiconductor region 43 formed in a p-well region 42 in the semiconductor substrate 50 and an n-type semiconductor region 44 formed near the center of the p-type semiconductor region 43. The n-type semiconductor region 44 functions as, for example, a photoelectric conversion region that generates a charge according to the amount of incident light, and the p-type semiconductor region 43 functions as a region that forms a potential gradient for collecting the charge generated by photoelectric conversion into the n-type semiconductor region 44.

For example, an IR filter 41 that selectively transmits IR light is disposed on the light incident surface side of the photoelectric conversion unit PD2. The IR filter 41 may be disposed, for example, in the insulating layer 53 provided on the back surface side of the semiconductor substrate 50. By disposing the IR filter 41 on the light incident surface of the photoelectric conversion unit PD2, it is possible to suppress the incidence of visible light on the photoelectric conversion unit PD2, and thus, it is possible to improve the S/N ratio of IR light to visible light. This makes it possible to obtain a more accurate detection result of IR light.

For example, a fine uneven structure is provided on the light incident surface of the semiconductor substrate 50 in order to suppress reflection of incident light (IR light in this example). This uneven structure may be a structure called a moth-eye structure, or may be an uneven structure having a size and a pitch different from those of the moth-eye structure.

On the front surface (lower surface in the drawing) side of the semiconductor substrate 50, that is, on the element formation surface side, there is provided a vertical transistor 45 that causes the charge generated in the photoelectric conversion unit PD2 to flow out to the address event detection circuit 210. The gate electrode of the vertical transistor 45 reaches the n-type semiconductor region 44 from the surface of the semiconductor substrate 50, and is connected to the address event detection circuit 210 via the wirings 65 and 66 (part of the transfer control line of the pixel drive line LD2) formed in an interlayer insulating film 56.

(Pixel Isolation Structure)

The semiconductor substrate 50 is provided with a pixel isolation part 54 that electrically isolates the plurality of unit pixels 110 from each other, and the photoelectric conversion unit PD2 is provided in each region partitioned by the pixel isolation part 54. For example, when the image sensor 100 is viewed from the back surface (upper surface in the drawing) side of the semiconductor substrate 50, the pixel isolation part 54 has, for example, a lattice shape interposed between the plurality of unit pixels 110, and each photoelectric conversion unit PD2 is formed in each region partitioned by the pixel isolation part 54.

For the pixel isolation part 54, for example, a reflective film that reflects light such as tungsten (W) or aluminum (Al) may be used. As a result, the incident light entering the photoelectric conversion unit PD2 can be reflected by the pixel isolation part 54, so that the optical path length of the incident light in the photoelectric conversion unit PD2 can be increased. In addition, since the pixel isolation part 54 has a light reflection structure, it is possible to reduce leakage of light to adjacent pixels, and thus, it is also possible to further improve image quality, distance measurement accuracy, and the like. Note that the configuration in which the pixel isolation part 54 has the light reflection structure is not limited to the configuration using the reflection film, and can be realized, for example, by using a material having a refractive index different from that of the semiconductor substrate 50 for the pixel isolation part 54.

For example, a fixed charge film 55 is provided between the semiconductor substrate 50 and the pixel isolation part 54. The fixed charge film 55 is formed using, for example, a high dielectric having a negative fixed charge so that a positive charge (hole) accumulation region is formed at an interface part with the semiconductor substrate 50 and generation of a dark current is suppressed. Since the fixed charge film 55 is formed to have a negative fixed charge, an electric field is applied to the interface with a semiconductor substrate 138 by the negative fixed charge, and a positive charge (hole) accumulation region is formed.

The fixed charge film 55 can be formed of, for example, a hafnium oxide film (HfO₂ film). In addition, the fixed charge film 55 can be formed to contain at least one of oxides such as hafnium, zirconium, aluminum, tantalum, titanium, magnesium, yttrium, and lanthanoid elements, for example.

Note that FIG. 8 illustrates a case where the pixel isolation part 54 has a so-called full trench isolation (FTI) structure reaching from the front surface to the back surface of the semiconductor substrate 50, but is not limited thereto. For example, various element isolation structures such as a so-called deep trench isolation (DTI) structure in which the pixel isolation part 54 is formed from the back surface or the front surface of the semiconductor substrate 50 to the vicinity of the middle of the semiconductor substrate 50 can be adopted.

(Pupil Correction)

A planarization film 52 made of a silicon oxide film, a silicon nitride film, or the like is provided on the upper surface of the color filter 31. The upper surface of the planarization film 52 is planarized by, for example, chemical mechanical polishing (CMP), and an on-chip lens 51 for each unit pixel 110 is provided on the planarized upper surface. The on-chip lens 51 of each unit pixel 110 has such a curvature that incident light is collected in the photoelectric conversion units PD1 and PD2. Note that a positional relationship among the on-chip lens 51, the color filter 31, the IR filter 41, and the photoelectric conversion unit PD2 in each unit pixel 110 may be adjusted according to, for example, the distance (image height) from the center of the pixel array unit 101 (pupil correction).

Furthermore, in the structure illustrated in FIG. 8, a light shielding film for preventing obliquely incident light from leaking into the adjacent pixel may be provided. The light shielding film can be located above the pixel isolation part 54 provided inside the semiconductor substrate 50 (upstream in the optical path of the incident light). However, when pupil correction is performed, the position of the light shielding film may be adjusted according to, for example, the distance (image height) from the center of the pixel array unit 101. Such a light shielding film may be provided, for example, in the sealing film 32 or the planarization film 52. Furthermore, as a material of the light shielding film, for example, a light shielding material such as aluminum (Al) or tungsten (W) may be used.

1.7 Organic Material

In the first embodiment, when an organic semiconductor is used as the material of the photoelectric conversion film 34, the layer structure of the photoelectric conversion film 34 can have the following structure. However, in the case of the laminated structure, the lamination order can be appropriately changed.

(1) Single-layer structure of p-type organic semiconductor

(2) Single-layer structure of n-type organic semiconductor

(3-1) Laminated structure of p-type organic semiconductor layer/n-type organic semiconductor layer

(3-2) Laminated structure of p-type organic semiconductor layer/mixed layer (bulk heterostructure) of p-type organic semiconductor and n-type organic semiconductor/n-type organic semiconductor layer

(3-3) Laminated structure of p-type organic semiconductor layer/mixed layer (bulk hetero structure) of p-type organic semiconductor and n-type organic semiconductor

(3-4) Laminated structure of n-type organic semiconductor layer/mixed layer (bulk heterostructure) of p-type organic semiconductor and n-type organic semiconductor

(4) Mixed layer of p-type organic semiconductor and p-type organic semiconductor (bulk heterostructure)

Here, examples of the p-type organic semiconductor include a naphthalene derivative, an anthracene derivative, a phenanthrene derivative, a pyrene derivative, a perylene derivative, a tetracene derivative, a pentacene derivative, a quinacridone derivative, a thiophene derivative, a thienothiophene derivative, a benzothiophene derivative, a benzothienobenzothiophene derivative, a triallylamine derivative, a carbazole derivative, a perylene derivative, a picene derivative, a chrysene derivative, a fluoranthene derivative, a phthalocyanine derivative, a subphthalocyanine derivative, a subporphyrazine derivative, a metal complex having a heterocyclic compound as a ligand, a polythiophene derivative, a polybenzothiadiazole derivative, a polyfluorene derivative, and the like.

Examples of the n-type organic semiconductor include fullerene and a fullerene derivative<for example, fullerene (higher fullerenes, endohedral fullerenes, etc.) such as C60, C70, or C74, or a fullerene derivative (for example, fullerene fluoride, PCBM fullerene compound, fullerene multimer, and the like)>, an organic semiconductor having a larger (deeper) HOMO and LUMO than a p-type organic semiconductor, and a transparent inorganic metal oxide.

Specific examples of the n-type organic semiconductor include heterocyclic compounds containing a nitrogen atom, an oxygen atom, and a sulfur atom, such as pyridine derivatives, pyrazine derivatives, pyrimidine derivatives, triazine derivatives, quinoline derivatives, quinoxaline derivatives, isoquinoline derivatives, acridine derivatives, phenazine derivatives, phenanthroline derivatives, tetrazole derivatives, pyrazole derivatives, imidazole derivatives, thiazole derivatives, oxazole derivatives, imidazole derivatives, benzimidazole derivatives, benzotriazole derivatives, benzoxazole derivatives, benzoxazole derivatives, carbazole derivatives, benzofuran derivatives, dibenzofuran derivatives, subporphyrazine derivatives, polyphenylenevinylene derivatives, polybenzothiadiazole derivatives, and polyfluorene derivatives.

Examples of a group or the like contained in the fullerene derivative include halogen atom; linear, branched or cyclic alkyl or phenyl groups; Group having linear or condensed aromatic compound; Group having halide; Partial fluoroalkyl group; Perfluoroalkyl group; silylalkyl group; silyl alkoxy group; Arylsilyl group; Arylsulfanyl group; alkylsulfanyl group; arylsulfonyl group; alkylsulfonyl group; Aryl sulfide group; alkyl sulfide group; Amino group; alkylamino group; arylamino group; Hydroxy group; Alkoxy group; Acylamino group; Acyloxy group; carbonyl group; Carboxy group; Carboxamide group; Carboalkoxy group; acyl group; sulfonyl group; Cyano group; Nitro group; Group having chalcogenide; Phosphine group; phosphon group; and these derivatives.

The film thickness of the photoelectric conversion film 34 made of the organic material as described above is not limited to the following value, but may be, for example, 1×10⁻⁸ m (meter) to 5×10⁻⁷ m, preferably 2.5×10⁻⁸ m to 3×10⁻⁷ m, more preferably 2.5×10⁻⁸ m to 2×10⁻⁷ m, and still more preferably 1×10⁻⁷ m to 1.8×10⁻⁷ m. Note that the organic semiconductor is often classified into a p-type and an n-type, but the p-type means that holes are easily transported, and the n-type means that electrons are easily transported, and the organic semiconductor is not limited to the interpretation that it has holes or electrons as a majority carrier of thermal excitation like the inorganic semiconductor.

Examples of a material constituting the photoelectric conversion film 34 that photoelectrically converts light having a green wavelength include a rhodamine dye, a melacyanine dye, a quinacridone derivative, and a subphthalocyanine dye (subphthalocyanine derivative).

Furthermore, examples of a material constituting the photoelectric conversion film 34 that photoelectrically converts blue light include a coumaric acid dye, tris-8-hydroxyquinoline aluminum (Alq3), a melacyanine dye, and the like.

Moreover, examples of a material constituting the photoelectric conversion film 34 that photoelectrically converts red light include phthalocyanine dyes and subphthalocyanine dyes (subphthalocyanine derivatives).

Further, as the photoelectric conversion film 34, a panchromatic photosensitive organic photoelectric conversion film that is sensitive to substantially all visible light from the ultraviolet region to the red region can be used.

1.8 Planar Structure Example

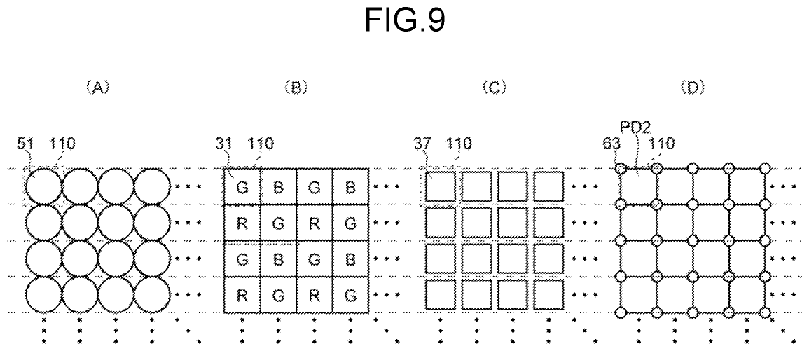

Next, a planar structure example of the pixel array unit according to the present embodiment will be described. FIG. 9 is a diagram illustrating a planar layout example of each layer of the pixel array unit according to the first embodiment, in which (A) illustrates a planar layout example of the on-chip lens 51, (B) illustrates a planar layout example of the color filter 31, (C) illustrates a planar layout example of the storage electrode 37, and (D) illustrates a planar layout example of the photoelectric conversion unit PD2. Note that, in FIG. 9, (A) to (D) illustrate planar layout examples of surfaces parallel to the element formation surface of the semiconductor substrate 50. Furthermore, in the present description, a case where a 2×2 pixel Bayer array including a pixel (Hereinafter, referred to as an R pixel 10r.) that selectively detects a red (R) wavelength component, a pixel (Hereinafter, referred to as a G pixel 10g.) that selectively detects a green (G) wavelength component, and a pixel (Hereinafter, referred to as a B pixel 10b.) that selectively detects light of a blue (B) wavelength component is used as a unit array will be exemplified.

As illustrated in (A) to (D) of FIG. 9, in the present embodiment, one on-chip lens 51, one color filter 31, one storage electrode 37, and one photoelectric conversion unit PD2 are provided for one unit pixel 110. Note that, in the present description, one storage electrode 37 corresponds to one RGB pixel 10, and one photoelectric conversion unit PD2 corresponds to one EVS pixel 20.

As described above, in one unit pixel 110, by arranging one RGB pixel 10 and one EVS pixel 20 along the traveling direction of the incident light, it is possible to improve coaxiality with respect to the incident light between the RGB pixel 10 and the EVS pixel 20, and thus, it is possible to suppress spatial deviation occurring between the RGB image and the EVS image. Accordingly, it is possible to improve the accuracy of the results obtained by integrally processing the information (the RGB image and the EVS image) acquired by the different sensors.

1.9 Wiring Example of Pixel Drive Line

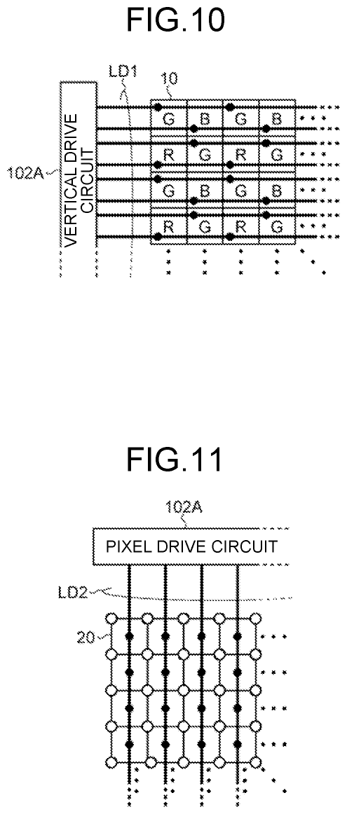

Next, wiring examples of the pixel drive line LD1 connecting the RGB pixel 10 and the vertical drive circuit 102A and the pixel drive line LD2 connecting the EVS pixel 20 and the vertical drive circuit 102A will be described. FIG. 10 is a plan view illustrating an example of wiring of a pixel drive line for the RGB pixel according to the first embodiment, and FIG. 11 is a plan view illustrating an example of wiring of a pixel drive line for the EVS pixel according to the first embodiment.

As illustrated in FIGS. 10 and 11, for example, the pixel drive line LD1 for driving the RGB pixel 10 and the pixel drive line LD2 for driving the EVS pixel 20 may be wired so as to be orthogonal to each other. However, the present invention is not limited thereto, and the RGB drive line LD1 and the IR drive line LD2 may be wired in parallel. In this case, the pixel drive line LD1 and the pixel drive line LD2 may supply various control signals to the pixel array unit 101 from the same side or from different sides.

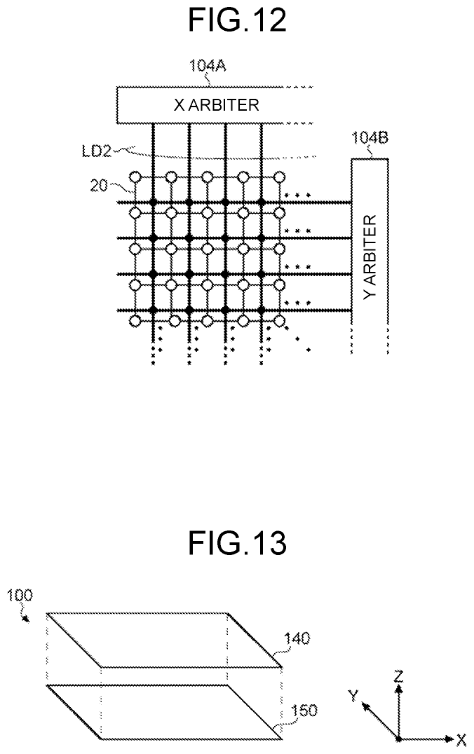

Furthermore, FIG. 12 is a plan view illustrating an example of wiring of signal lines for the EVS pixel according to the first embodiment. As illustrated in FIG. 12, the X arbiter 104A is connected to the EVS pixels 20 of each column via, for example, signal lines extending in the column direction, and the Y arbiter 104B is connected to the EVS pixels 20 of each row via, for example, signal lines extending in the row direction.

1.10 Laminated Structure Example of Image Sensor

FIG. 13 is a diagram illustrating a laminated structure example of the image sensor according to the first embodiment. As illustrated in FIG. 13, the image sensor 100 has a structure in which a pixel chip 140 and a circuit chip 150 are vertically laminated. The pixel chip 140 is, for example, a semiconductor chip including the pixel array unit 101 in which unit pixels 110 including an RGB pixel 10 and an EVS pixel 20 are arranged, and the circuit chip 150 is, for example, a semiconductor chip in which the pixel circuit and the address event detection circuit 210 illustrated in FIG. 6 are arranged.

For bonding the pixel chip 140 and the circuit chip 150, for example, so-called direct bonding can be used, in which the bonding surfaces are flattened and the bonding surfaces are bonded to each other by an electronic force. However, the present invention is not limited thereto, and for example, so-called Cu—Cu bonding in which copper (Cu) electrode pads formed on the joint surfaces are bonded to each other, bump bonding, or the like can also be used.

Furthermore, the pixel chip 140 and the circuit chip 150 are electrically connected via a connection part such as a through-silicon via (TSV) penetrating the semiconductor substrate, for example. For the connection using the TSV, for example, a so-called twin TSV method in which two TSVs, that is, a TSV provided in the pixel chip 140 and a TSV provided from the pixel chip 140 to the circuit chip 150 are connected by an outer surface of the chip, a so-called shared TSV method in which both are connected by a TSV penetrating from the pixel chip 140 to the circuit chip 150, or the like can be adopted.

However, when Cu—Cu bonding or bump bonding is used for bonding the pixel chip 140 and the circuit chip 150, the two may be electrically connected via a Cu—Cu bonding part or a bump bonding part.

1.11 Recognition Operation Example

Next, an example of a recognition operation executed by the recognition system according to the present embodiment will be described. Note that, here, a recognition operation example of the recognition system 1000 described with reference to FIG. 1 will be described with reference to the electronic device 1 described with reference to FIGS. 2 and 3. However, as described above, the recognition operation may be realized so as to be completed in the image sensor 100, may be realized by processing image data acquired by the image sensor 100 in the application processor 1100, or may be realized by executing a part of processing in the image sensor 100 on image data acquired by the image sensor 100 and executing the rest in the application processor 1100.

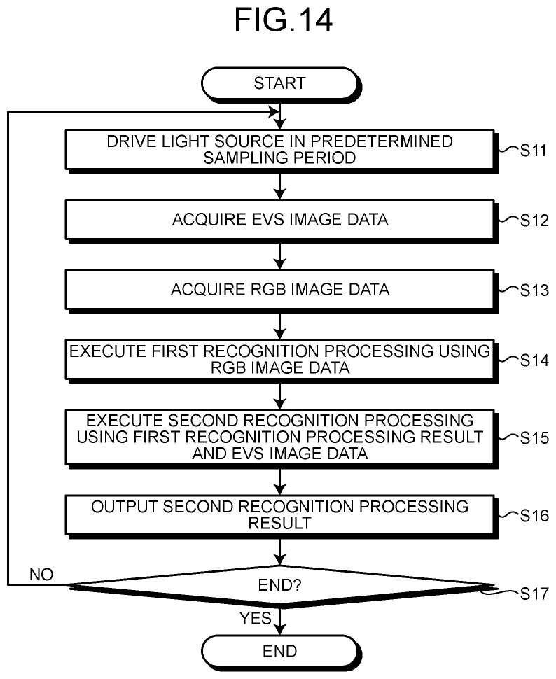

FIG. 14 is a flowchart illustrating an example of a recognition operation according to the first embodiment. As illustrated in FIG. 14, in the present operation, first, the system control unit 1050 drives the laser light source 1010 at a predetermined sampling period to cause the laser light source 1010 to emit irradiation light at a predetermined sampling period (Step S11), and drives the EVS sensor unit 1003 (see FIG. 1) in the image sensor 100 at a predetermined sampling period in synchronization with the driving of the laser light source 1010 to acquire EVS image data at a predetermined sampling period (Step S12).

Furthermore, the system control unit 1050 acquires RGB image data by driving the RGB sensor unit 1001 (see FIG. 1) in the image sensor 100 (Step S13).

Note that the acquisition of the RGB image data may be executed in parallel with the acquisition of the EVS image data, or may be executed in a period different from the acquisition period of the EVS image data. At this time, either the acquisition of the RGB image data or the acquisition of the EVS image data may be executed first. Furthermore, the RGB image data may be acquired once with respect to the acquisition of the EVS image data performed K times (K is an integer of 1 or more).

Among the RGB image data and the EVS image data acquired in this manner, the RGB image data is subjected to predetermined processing in the RGB image processing unit 1002 and then input to the recognition processing unit 1005. Note that, in Step S11 or S12, in a case where ROI information is input from the event signal processing unit 1004 to the RGB sensor unit 1001 or the RGB image processing unit 1002 in FIG. 1, RGB image data and/or EVS image data of a region corresponding to the ROI information may be input to the recognition processing unit 1005.

Next, the recognition processing unit 1005 executes recognition processing (first recognition processing) of an object existing within an angle of view of the image sensor 100 by using the input RGB image data (Step S14). As in the first embodiment, recognition processing such as pattern recognition, recognition processing by artificial intelligence, or the like may be used for the first recognition processing.

Next, the recognition processing unit 1005 executes recognition processing (second recognition processing) for more accurately recognizing an object existing within the angle of view using the result of the first recognition processing and the EVS image data (Step S15). For the second recognition processing, similarly to the first recognition processing, recognition processing such as pattern recognition, recognition processing by artificial intelligence, or the like may be used.

Next, the recognition processing unit 1005 outputs the result of the second recognition processing obtained in Step S15 to the outside via the interface unit 1006, for example (Step S16). Note that the recognition processing unit 1005 may execute a part of the first recognition processing and output the result (intermediate data or the like) to the outside, or may execute a part of the second recognition processing and output the result (intermediate data or the like).

Thereafter, a recognition system 370 determines whether or not to end the present operation (Step S17), and if not (NO in Step S17), returns to Step S11. On the other hand, when the processing is ended (YES in Step S17), the recognition system 370 ends the present operation.

1.12 Example of Circuit Configuration of EVS Pixel

Next, a specific circuit configuration of the EVS pixel 20 will be described with some examples. As described above, the EVS pixel 20 has an event detection function of detecting that the luminance change exceeds a predetermined threshold as an event.

The EVS pixel 20 detects whether or not an event has occurred based on whether or not the change amount of the photocurrent exceeds a predetermined threshold. The event includes, for example, an on-event indicating that the change amount of the photocurrent exceeds an upper limit threshold and an off-event indicating that the change amount falls below a lower limit threshold. Furthermore, the event data (event information) indicating the occurrence of an event includes, for example, one bit indicating a detection result of an on-event and one bit indicating a detection result of an off-event. Note that the EVS pixel 20 can be configured to have a function of detecting only an on-event, or can be configured to have a function of detecting only an off-event.

1.12.1 First Circuit Configuration Example

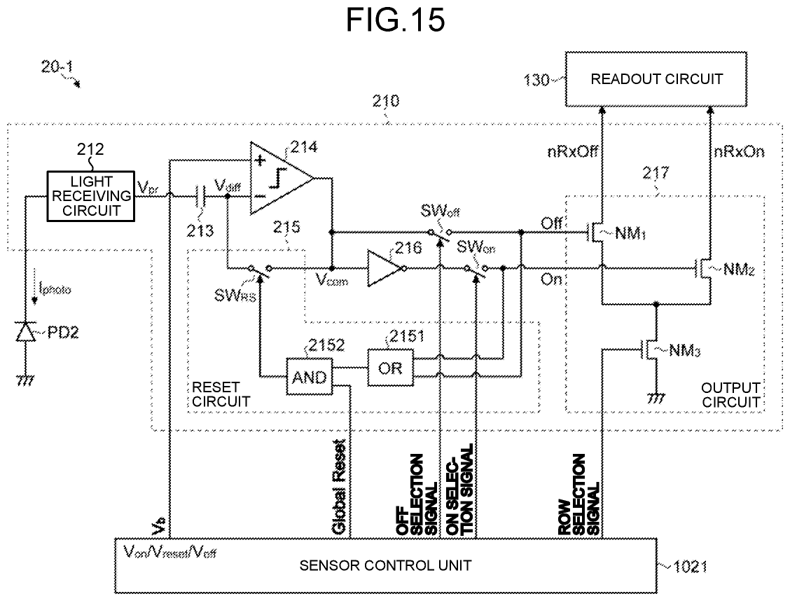

The address event detection circuit 210 of the EVS pixel 20-1 according to a first circuit configuration example has a configuration for detecting an on-event and detecting an off-event in a time division manner using one comparator. FIG. 15 illustrates a circuit diagram of the EVS pixel 20 according to the first circuit configuration example. The EVS pixel 20 according to the first circuit configuration example includes a photoelectric conversion unit PD2 and an address event detection circuit 210, and the address event detection circuit 210 has a circuit configuration including a light receiving circuit 212, a memory capacity 213, a comparator 214, a reset circuit 215, an inverter 216, and an output circuit 217. The EVS pixel 20 detects an on-event and an off-event under the control of the sensor control unit 1021.

In the photoelectric conversion unit PD2, a first electrode (anode electrode) is connected to an input terminal of the light receiving circuit 212, a second electrode (cathode electrode) is connected to a ground node which is a reference potential node, and the photoelectric conversion unit PD2 photoelectrically converts incident light to generate a charge of a charge amount corresponding to intensity (light amount) of light. Furthermore, the photoelectric conversion unit PD2 converts the generated charge into a photocurrent Iₚₕₒₜₒ.

The light receiving circuit 212 converts the photocurrent Iₚₕₒₜₒ according to the intensity (light amount) of light detected by the photoelectric conversion unit PD2 into a voltage Vₚᵣ. Here, a relationship between the voltage Vₚᵣ and the light intensity is usually a logarithmic relationship. That is, the light receiving circuit 212 converts the photocurrent Iₚₕₒₜₒ corresponding to the intensity of light applied to the light receiving surface of the photoelectric conversion unit PD2 into a voltage Vₚᵣ that is a logarithmic function. However, the relationship between the photocurrent Iₚₕₒₜₒ and the voltage Vₚᵣ is not limited to the logarithmic relationship.

The voltage Vₚᵣ according to the photocurrent Iₚₕₒₜₒ output from the light receiving circuit 212 passes through the memory capacity 213 and then becomes an inversion (−) input which is the first input of the comparator 214 as the voltage V_{diff}. The comparator 214 is usually configured by a differential pair transistor. The comparator 214 uses the threshold voltage V_{b} provided from the sensor control unit 1021 as a non-inverting (+) input that is the second input, and detects an on-event and an off-event in a time division manner. Furthermore, after the detection of the on-event/off-event, the reset circuit 215 resets the EVS pixel 20.

The sensor control unit 1021 outputs the voltage Vₒₙ as the threshold voltage V_{b} in a time division manner at a stage of detecting an on-event, outputs the voltage V_{off} at a stage of detecting an off-event, and outputs the voltage Vᵣₑₛₑₜ at a stage of resetting. The voltage Vᵣₑₛₑₜ is set to a value between the voltage Vₒₙ and the voltage V_{off}, preferably an intermediate value between the voltage Vₒₙ and the voltage V_{off}. Here, the “intermediate value” means to include not only a case where the value is strictly an intermediate value but also a case where the value is substantially an intermediate value, and existence of various variations caused by design or manufacturing is allowed.

Furthermore, the sensor control unit 1021 outputs an ON selection signal to the EVS pixel 20 at a stage of detecting an on-event, outputs an OFF selection signal at a stage of detecting an off-event, and outputs a global reset signal (Global Reset) at a stage of performing reset. The ON selection signal is provided as a control signal to a selection switch SWₒₙ provided between the inverter 216 and the output circuit 217. The OFF selection signal is provided as a control signal to a selection switch SW_{off} provided between the comparator 214 and the output circuit 217.

In a stage of detecting an on-event, the comparator 214 compares the voltage Vₒₙ with the voltage V_{diff}, and when the voltage V_{diff} exceeds the voltage Vₒₙ, outputs on-event information On indicating that the change amount of the photocurrent Iₚₕₒₜₒ exceeds an upper limit threshold as a comparison result. The on-event information On is inverted by the inverter 216 and then supplied to the output circuit 217 through the selection switch SWₒₙ.

In the step of detecting the off-event, the comparator 214 compares the voltage V_{off} with the voltage V_{diff}, and when the voltage V_{diff} becomes lower than the voltage V_{off}, outputs off-event information Off indicating that the change amount of the photocurrent Iₚₕₒₜₒ becomes lower than a lower limit threshold as a comparison result. The off-event information Off is supplied to the output circuit 217 through the selection switch SW_{off}.

The reset circuit 215 includes a reset switch SW_{RS}, a 2-input OR circuit 2151, and a 2-input AND circuit 2152. The reset switch SW_{RS} is connected between the inverting (−) input terminal and the output terminal of the comparator 214, and is turned on (closed) to selectively short-circuit between the inverting input terminal and the output terminal.

The OR circuit 2151 receives two inputs of the on-event information On via the selection switch SWₒₙ and the off-event information Off via the selection switch SW_{off}. The AND circuit 2152 uses the output signal of the OR circuit 2151 as one input, uses the global reset signal provided from the sensor control unit 1021 as the other input, and turns on (closes) the reset switch SW_{RS} when either the on-event information On or the off-event information Off is detected and the global reset signal is in the active state.

As described above, when the output signal of the AND circuit 2152 becomes the active state, the reset switch SW_{RS} short-circuits between the inverting input terminal and the output terminal of the comparator 214, and performs global reset on the EVS pixel 20. As a result, the reset operation is performed only for the EVS pixel 20 in which the event is detected.

The output circuit 217 includes an off-event output transistor NM₁, an on-event output transistor NM₂, and a current source transistor NM₃. The off-event output transistor NM₁ has a memory (not illustrated) for holding off-event information Off at a gate part thereof. This memory consists of the gate parasitic capacitance of the off-event output transistor NM₁.

Similarly to the off-event output transistor NM₁, the on-event output transistor NM₂ has a memory (not illustrated) for holding on-event information On at a gate part thereof. This memory consists of the gate parasitic capacitance of the on-event output transistor NM₂.

In the readout stage, the off-event information Off held in the memory of the off-event output transistor NM₁ and the on-event information On held in the memory of the on-event output transistor NM₂ are transferred to a readout circuit 130 through the output line nRxOff and the output line nRxOn for each pixel row of the pixel array unit 101 when a row selection signal is provided from the sensor control unit 1021 to the gate electrode of the current source transistor NM₃. The readout circuit 130 is, for example, a circuit provided in the EVS signal processing circuit 103B (see FIG. 4).

As described above, the EVS pixel 20 according to the first circuit configuration example has an event detection function of detecting an on-event and detecting an off-event in a time-division manner under the control of the sensor control unit 1021 using one comparator 214.

1.12.2 Second Circuit Configuration Example

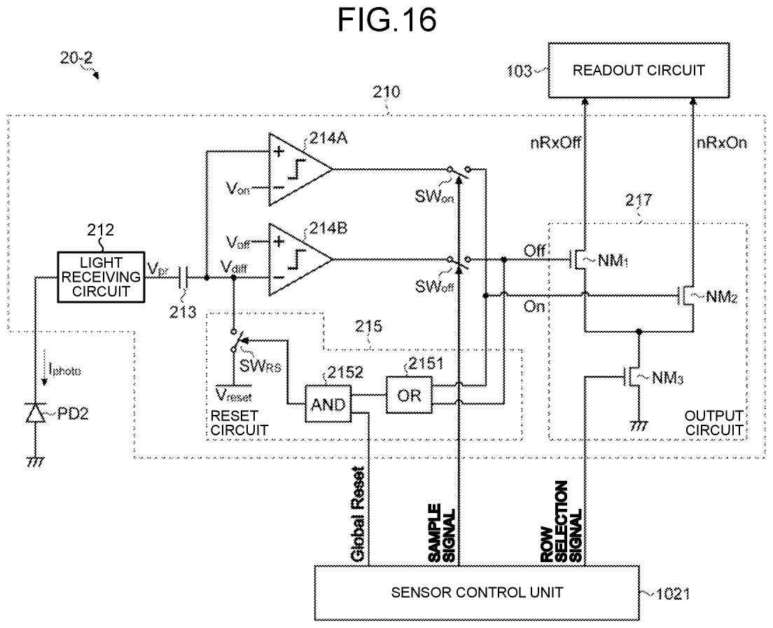

The address event detection circuit 210 of the EVS pixel 20-2 according to a second circuit configuration example is an example in which detection of an on-event and detection of an off-event are performed in parallel (simultaneously) using two comparators. FIG. 16 illustrates a circuit diagram of the EVS pixel 20 according to the second circuit configuration example.

As illustrated in FIG. 16, the address event detection circuit 210 according to the second circuit configuration example includes a comparator 214A for detecting an on-event and a comparator 214B for detecting an off-event. In this manner, by performing event detection using the two comparators 214A and 214B, the on-event detection operation and the off-event detection operation can be executed in parallel. As a result, a faster operation can be realized for the on-event and off-event detection operations.

The comparator 214A for detecting an on-event is usually configured by a differential pair transistor. The comparator 214A sets a voltage V_{diff} corresponding to the photocurrent Iₚₕₒₜₒ as a non-inverting (+) input which is a first input, sets a voltage Vₒₙ as a threshold voltage V_{b} as an inverting (−) input which is a second input, and outputs on-event information On as a comparison result between the two. The comparator 214B for off-event detection is also usually configured by a differential pair transistor. The comparator 214B sets a voltage V_{diff} corresponding to the photocurrent Iₚₕₒₜₒ as an inverting input which is a first input, sets a voltage V_{off} as a threshold voltage V_{b} as a non-inverting input which is a second input, and outputs off-event information Off as a comparison result between the two.

A selection switch SWₒₙ is connected between the output terminal of the comparator 214A and the gate electrode of the on-event output transistor NM₂ of the output circuit 217. A selection switch SW_{off} is connected between the output terminal of the comparator 214B and the gate electrode of the off-event output transistor NM₁ of the output circuit 217. On (close)/off (open) control of the selection switch SWₒₙ and the selection switch SW_{off} is performed by a sample signal output from the sensor control unit 1021.

On-event information On that is the comparison result of the comparator 214A is held in the memory of the gate part of the on-event output transistor NM₂ via the selection switch SWₒₙ. The memory for holding the on-event information On includes the gate parasitic capacitance of the on-event output transistor NM₂. Off-event information Off that is a comparison result of the comparator 214B is held in the memory of the gate part of the off-event output transistor NM₁ via the selection switch SW_{off}. The memory for holding the off-event information Off includes the gate parasitic capacitance of the off-event output transistor NM₁.

The on-event information On held in the memory of the on-event output transistor NM₂ and the off-event information Off held in the memory of the off-event output transistor NM₁ are transferred to the readout circuit 130 through the output line nRxOn and the output line nRxOff for each pixel row of the pixel array unit 101 by applying a row selection signal from the sensor control unit 1021 to the gate electrode of the current source transistor NM₃.

As described above, the EVS pixel 20 according to the second circuit configuration example has an event detection function of performing detection of an on-event and detection of an off-event in parallel (simultaneously) under the control of the sensor control unit 1021 using the two comparators 214A and 214B.

1.12.3 Third Circuit Configuration Example

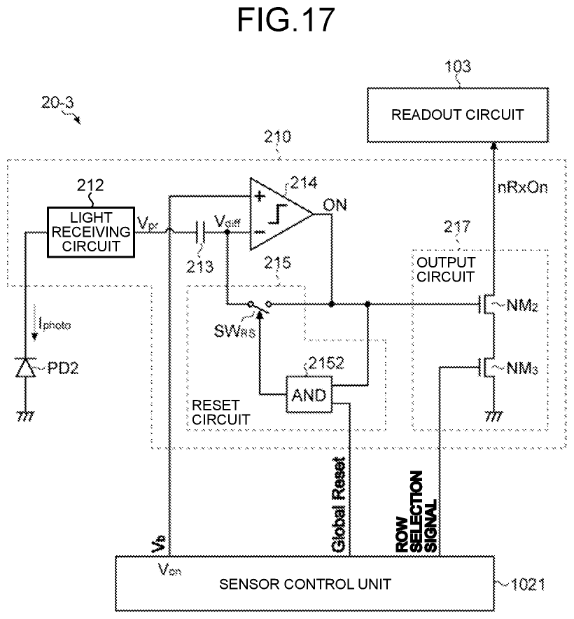

The address event detection circuit 210 of the EVS pixel 20-3 according to a third circuit configuration example is an example of detecting only an on-event. FIG. 17 illustrates a circuit diagram of the EVS pixel 20 according to the third circuit configuration example.

The address event detection circuit 210 according to the third circuit configuration example includes one comparator 214. The comparator 214 sets a voltage V_{diff} corresponding to the photocurrent Iₚₕₒₜₒ as an inverting (−) input which is a first input, and sets a voltage Vₒₙ provided as a threshold voltage V_{b} from the sensor control unit 1021 as a non-inverting (+) input which is a second input, and compares both inputs to output the on-event information On as a comparison result. Here, by using an N-type transistor as a differential pair transistor constituting the comparator 214, the inverter 216 used in the first circuit configuration example (see FIG. 17) can be made unnecessary.

On-event information On that is the comparison result of the comparator 214 is held in the memory of the gate part of the on-event output transistor NM₂. The memory for holding the on-event information On includes the gate parasitic capacitance of the on-event output transistor NM₂. The on-event information On held in the memory of the on-event output transistor NM₂ is transferred to the readout circuit 130 through the output line nRxOn for each pixel row of the pixel array unit 101 when a row selection signal is provided from the sensor control unit 1021 to the gate electrode of the current source transistor NM₃.

As described above, the EVS pixel 20 according to the third circuit configuration example has an event detection function of detecting only the on-event information On under the control of the sensor control unit 1021 using one comparator 214.

1.12.4 Fourth Circuit Configuration Example

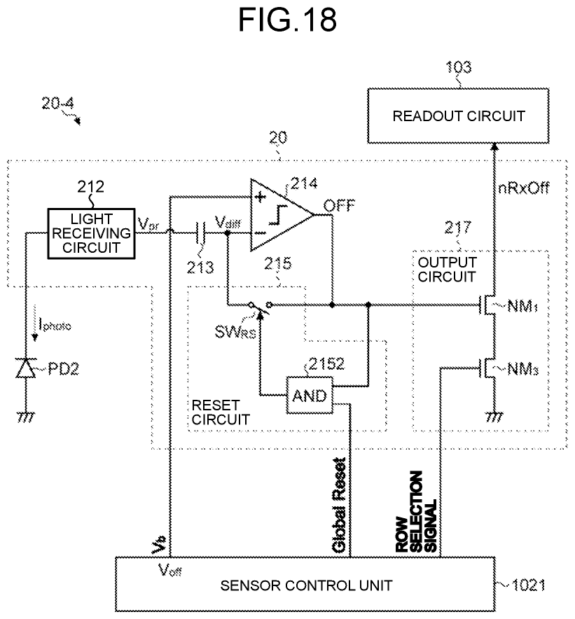

The address event detection circuit 210 of the EVS pixel 20-4 according to a fourth circuit configuration example is an example of detecting only an off-event. FIG. 18 illustrates a circuit diagram of the EVS pixel 20 according to the fourth circuit configuration example.

The address event detection circuit 210 according to the fourth circuit configuration example includes one comparator 214. The comparator 214 sets a voltage V_{diff} corresponding to the photocurrent Iₚₕₒₜₒ as an inverting (−) input which is a first input, and sets a voltage V_{off} provided as a threshold voltage V_{b} from the sensor control unit 1021 as a non-inverting (+) input which is a second input, and compares both inputs to output off-event information Off as a comparison result. A P-type transistor can be used as the differential pair transistor constituting the comparator 214.

Off-event information Off that is the comparison result of the comparator 214 is held in the memory of the gate part of the off-event output transistor NM₁. The memory holding the off-event information Off includes the gate parasitic capacitance of the off-event output transistor NM₁. The off-event information Off held in the memory of the off-event output transistor NM₁ is transferred to the readout circuit 130 through the output line nRxOff for each pixel row of the pixel array unit 101 when a row selection signal is provided from the sensor control unit 1021 to the gate electrode of the current source transistor NM₃.

As described above, the EVS pixel 20 according to the fourth circuit configuration example has an event detection function of detecting only the off-event information Off under the control of the sensor control unit 1021 using one comparator 214. Note that, in the circuit configuration of FIG. 18, the reset switch SW_{RS} is controlled by the output signal of the AND circuit 2152, but the reset switch SW_{RS} may be directly controlled by the global reset signal.

1.13 Synchronization Control Between Laser Light Source and Image Sensor

In the electronic device 1 using the image sensor 100 including the EVS pixel 20 according to the first circuit configuration example, the second circuit configuration example, the third circuit configuration example, or the fourth circuit configuration example, in the present embodiment, the laser light source 1010 and the image sensor 100 are controlled in synchronization under the control of the system control unit 1050.

By synchronously controlling the laser light source 1010 and the image sensor 100, it is possible to prevent other event information from being mixed and output in the event information caused by the motion of the subject. As the event information other than the event information caused by the motion of the subject, for example, event information caused by a change in a pattern projected on the subject or background light can be exemplified. By preventing the other event information from being output in a mixed manner among the event information caused by the motion of the subject, the event information caused by the motion of the subject can be more reliably acquired, and the process of separating the event information in the mixed state can be made unnecessary in the application processor that processes the event information.

Hereinafter, a specific example for synchronously controlling the laser light source 1010 and the image sensor 100 will be described. This synchronization control is performed by the light source drive unit 1011 and the sensor control unit 1021 under the control of the system control unit 1050 illustrated in FIGS. 2 and 3.

1.13.1 First Example

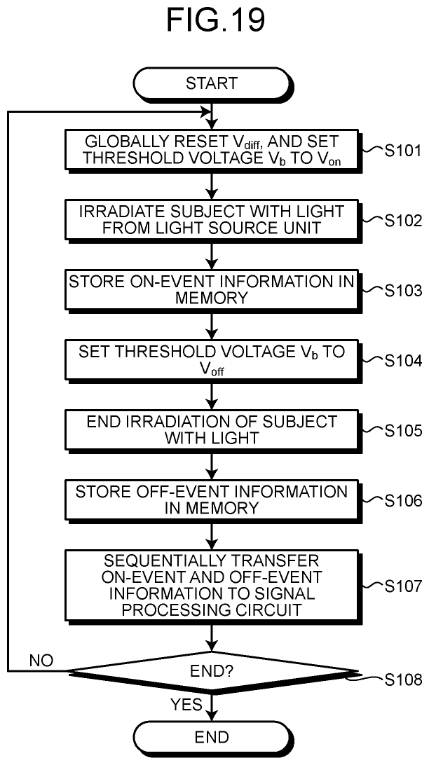

A first example is an example of synchronization control in a case where the EVS pixel 20 is the first circuit configuration example (that is, an example in which detection of an on-event and an off-event is performed in a time division manner using one comparator.). FIG. 19 illustrates a flowchart of synchronization control processing according to the first example.

The sensor control unit 1021 globally resets a voltage V_{diff} which is an inverting input of the comparator 214, and sets a threshold voltage V_{b} which is a non-inverting input of the comparator 214 to a voltage Vₒₙ for detecting an on-event (Step S101).

The global reset of the voltage V_{diff} may be performed after the event information is transferred to the readout circuit 130. Furthermore, the global reset of the voltage V_{diff} is performed by turning on (closing) the reset switch SW_{RS} in the reset circuit 215 illustrated in FIG. 15. These points are the same in each example described later.

Next, a subject (measurement target) is irradiated with light of a predetermined pattern from the laser light source 1010 which is a light source unit (Step S102). The laser light source 1010 is driven by the light source drive unit 1011 under the control of the system control unit 1050. This point is the same in examples described later.

Next, the sensor control unit 1021 stores on-event information On, which is a comparison result of the comparator 214, in the memory (Step S103). Here, the memory for storing the on-event information On is a gate parasitic capacitance of the on-event output transistor NM₂ in the output circuit 217.

Next, the sensor control unit 1021 sets the threshold voltage V_{b} to the off-event detection voltage V_{off} (Step S104). Next, the light source drive unit 1011 ends the irradiation of the subject with light (Step S105). Next, the sensor control unit 1021 stores off-event information Off, which is a comparison result of the comparator 214, in the memory (Step S106). Here, the memory for storing the off-event information Off is a gate parasitic capacitance of the off-event output transistor NM₁ in the output circuit 217.

Thereafter, the sensor control unit 1021 sequentially transfers the on-event information On stored in the gate parasitic capacitance of the on-event output transistor NM₂ and the off-event information Off stored in the gate parasitic capacitance of the off-event output transistor NM₁ to the readout circuit 130 (Step S107).

Thereafter, the system control unit 1050 determines whether or not to end the present operation (Step S108). In a case where the present operation ends (YES in Step S108), the system control unit ends a series of processing for synchronization control. In a case where the present operation does not end (NO in Step S108), the system control unit returns to Step S101, and executes subsequent operations.

1.13.2 Second Example

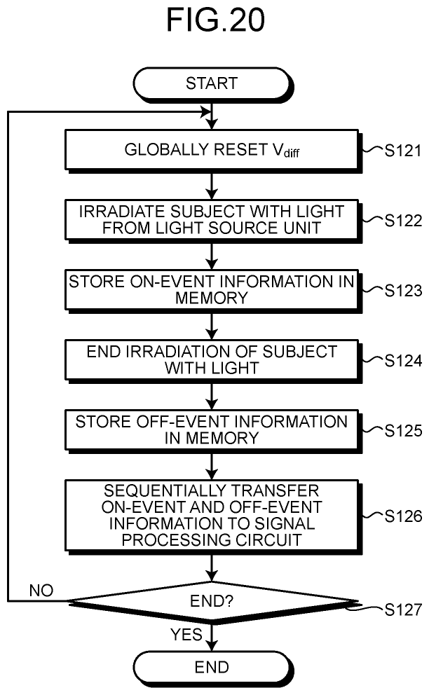

A second example is a synchronization control example in a case where the EVS pixel 20 is the second circuit configuration example (that is, an example in which detection of an on-event and an off-event is performed in parallel using two comparators.). FIG. 20 illustrates a flowchart of synchronization control processing according to the second example.

The sensor control unit 1021 globally resets a voltage V_{diff} which is an inverting input of the comparator 214 (Step S121). Next, the light source drive unit 1011 irradiates the subject with light of a predetermined pattern from the laser light source 1010 which is a light source unit (Step S122).

Next, the sensor control unit 1021 stores on-event information On, which is a comparison result of the comparator 214, in the memory (Step S123). Here, the memory for storing the on-event information On is a gate parasitic capacitance of the on-event output transistor NM₂ in the output circuit 217.

Next, the light source drive unit 1011 ends the irradiation of the subject with light (Step S124). Next, the sensor control unit 1021 stores off-event information Off, which is a comparison result of the comparator 214, in the memory (Step S125). Here, the memory for storing the off-event information Off is a gate parasitic capacitance of the off-event output transistor NM₁ in the output circuit 217.

Thereafter, the sensor control unit 1021 sequentially transfers the on-event information On stored in the gate parasitic capacitance of the on-event output transistor NM₂ and the off-event information Off stored in the gate parasitic capacitance of the off-event output transistor NM₁ to the readout circuit 130 (Step S126).

Thereafter, the system control unit 1050 determines whether or not to end the present operation (Step S127). In a case where the present operation ends (YES in Step S127), the system control unit ends a series of processing for synchronization control. In a case where the present operation does not end (NO in Step S127), the system control unit returns to Step S121, and executes subsequent operations.

1.13.3 Third Example

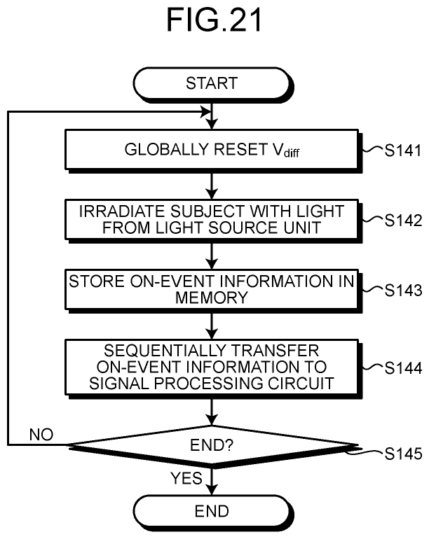

A third example is an example of synchronization control in a case where the EVS pixel 20 is the third circuit configuration example (that is, an example in which detection is performed only for an on-event by using one comparator.). FIG. 21 illustrates a flowchart of synchronization control processing according to the third example.

The sensor control unit 1021 globally resets a voltage V_{diff} which is an inverting input of the comparator 214 (Step S141). Next, the light source drive unit 1011 irradiates the subject with light of a predetermined pattern from the laser light source 1010 which is a light source unit (Step S142).

Next, the sensor control unit 1021 stores on-event information On, which is a comparison result of the comparator 214, in the memory (Step S143). Here, the memory for storing the on-event information On is a gate parasitic capacitance of the on-event output transistor NM₂ in the output circuit 217. Thereafter, the sensor control unit 1021 sequentially transfers the on-event information On stored in the gate parasitic capacitance of the on-event output transistor NM₂ to the readout circuit 130 (Step S144).

Thereafter, the system control unit 1050 determines whether or not to end the present operation (Step S145). In a case where the present operation ends (YES in Step S145), the system control unit ends a series of processing for synchronization control. In a case where the present operation does not end (NO in Step S145), the system control unit returns to Step S141, and executes subsequent operations.

1.13.4 Fourth Example

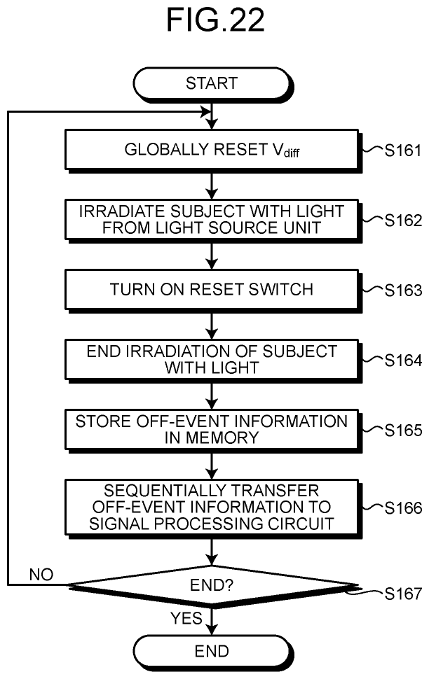

A fourth example is an example of synchronization control in a case where the EVS pixel 20 is the fourth circuit configuration example (that is, an example in which only an off-event is detected using one comparator). FIG. 22 illustrates a flowchart of synchronization control processing according to the fourth example.

The sensor control unit 1021 globally resets a voltage V_{diff} which is an inverting input of the comparator 214 (Step S161). Next, the light source drive unit 1011 irradiates the subject with light of a predetermined pattern from the laser light source 1010 which is a light source unit (Step S162).

Next, the sensor control unit 1021 turns on the reset switch SW_{RS} (Step S163). Next, the light source drive unit 1011 ends the irradiation of the subject with light (Step S164). Next, the sensor control unit 1021 stores off-event information Off, which is a comparison result of the comparator 214, in the memory (Step S165). Here, the memory for storing the off-event information Off is a gate parasitic capacitance of the off-event output transistor NM₁ in the output circuit 217.

Thereafter, the sensor control unit 1021 sequentially transfers the off-event information Off stored in the gate parasitic capacitance of the off-event output transistor NM₁ to the readout circuit 130 (Step S166).

Thereafter, the system control unit 1050 determines whether or not to end the present operation (Step S167). In a case where the present operation ends (YES in Step S167), the system control unit ends a series of processing for synchronization control. In a case where the present operation does not end (NO in Step S167), the system control unit returns to Step S161, and executes subsequent operations.

1.13.5 Fifth Example

Here, as a fifth example, a pixel arrangement example in a case where ON pixels 20a and OFF pixels 20b are mixed in the pixel array unit 101 will be described. In the present description, the “ON pixel 20a” is the EVS pixel 20 according to the third circuit configuration example, that is, a first pixel having a function of detecting only an on-event. Furthermore, the “OFF pixel 20b” is the EVS pixel 20 according to the fourth circuit configuration example, that is, a second pixel having a function of detecting only an off-event.

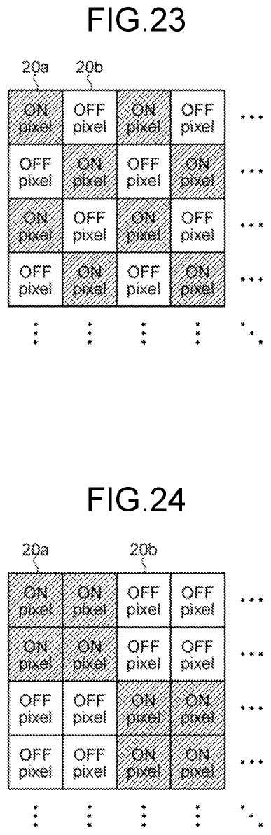

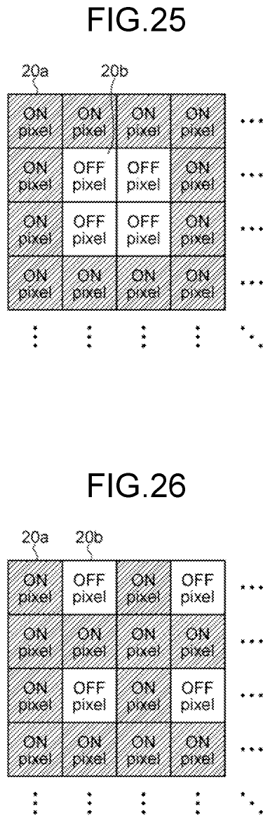

FIGS. 23 and 24 illustrate pixel arrangement examples (part 1) of the ON pixel 20a and the OFF pixel 20b according to the fifth example, and FIGS. 25 and 26 illustrate pixel arrangement examples (part 2) thereof. Here, in order to simplify the drawing, a pixel arrangement (pixel array) of a total of 16 pixels of four pixels in the X direction (row direction/horizontal direction) x four pixels in the Y direction (column direction/vertical direction) is illustrated. The arrangement of the EVS pixels 20 in the pixel array unit 101 may be, for example, repetition of the pixel arrangement illustrated in FIGS. 23 to 26.

The pixel arrangement example illustrated in FIG. 23 has a configuration in which ON pixels 20a and OFF pixels 20b are alternately arranged in both the X direction and the Y direction. The pixel arrangement example illustrated in FIG. 24 has a configuration in which a total of four pixels of two pixels in the X direction x two pixels in the Y direction are set as blocks (units), and blocks of ON pixels 20a and blocks of OFF pixels 20b are alternately arranged in both the X direction and the Y direction.

The pixel arrangement example illustrated in FIG. 25 has an arrangement configuration in which, among a total of 16 pixels, the middle four pixels are OFF pixels 20b, and the surrounding 12 pixels are ON pixels 20a. The pixel arrangement example illustrated in FIG. 26 has an arrangement configuration in which, in the pixel arrangement of 16 pixels in total, the pixels in the odd column and the even row are ON pixels 20a, and the remaining pixels are OFF pixels 20b.

Note that the pixel arrangement of the ON pixel 20a and the OFF pixel 20b exemplified here is an example, and the pixel arrangement is not limited thereto.

1.13.6 Sixth Example

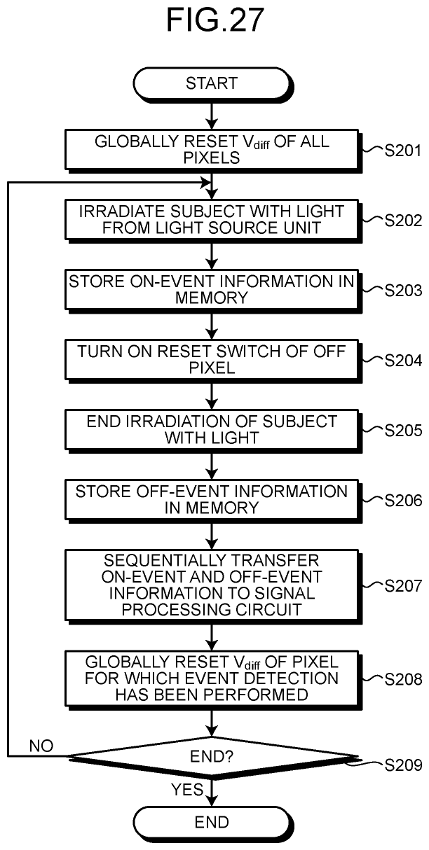

A sixth example is a synchronization control example (part 1) in the case of the fifth example, that is, a synchronization control example (part 1) in the case of pixel arrangement in which the ON pixels 20a and the OFF pixels 20b are mixed in the pixel array unit 101. FIG. 27 illustrates a flowchart of synchronization control processing according to the sixth example.

First, the sensor control unit 1021 globally resets all pixels including the ON pixels 20a and the OFF pixels 20b (Step S201). Next, the light source drive unit 1011 irradiates the subject with light of a predetermined pattern from the laser light source 1010 which is a light source unit (Step S202). Next, the sensor control unit 1021 stores the on-event information On detected by the ON pixel 20a in the memory (Step S203). Here, the memory for storing the on-event information On is a gate parasitic capacitance of the on-event output transistor NM₂ in the output circuit 217.

Next, the sensor control unit 1021 turns on the reset switch SW_{RS} of the OFF pixel 20b (Step S204). Next, the light source drive unit 1011 ends the irradiation of the subject with light (Step S205). Next, the sensor control unit 1021 stores the off-event information Off detected by the OFF pixel 20b in the memory (Step S206). Here, the memory for storing the off-event information Off is a gate parasitic capacitance of the off-event output transistor NM₁ in the output circuit 217.

Thereafter, the sensor control unit 1021 sequentially transfers the on-event information On and the off-event information Off to the readout circuit 130 (Step S207), and then globally resets the voltage V_{diff}, which is the inverting input of the comparator 214, for the pixel for which the event detection has been performed (Step S208).

Thereafter, the system control unit 1050 determines whether or not to end the present operation (Step S209). In a case where the present operation ends (YES in Step S209), the system control unit ends a series of processing for synchronization control. In a case where the present operation does not end (NO in Step S209), the system control unit returns to Step S202, and executes subsequent operations.

1.13.7 Seventh Example

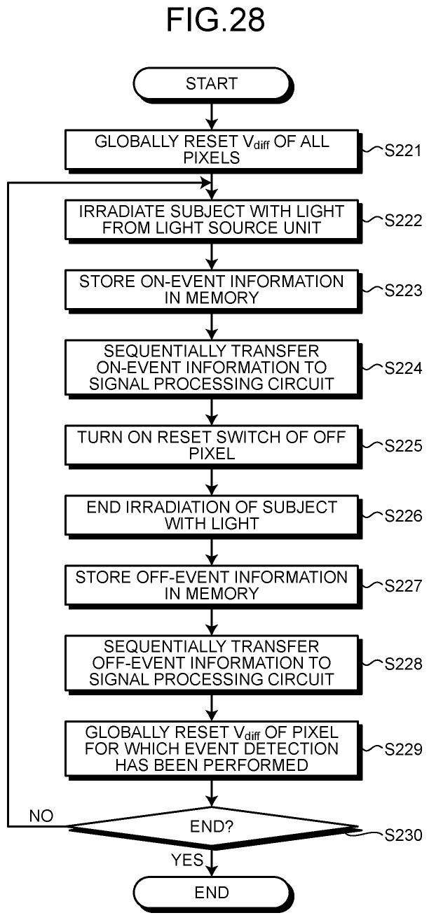

A seventh example is a synchronization control example (part 2) in the case of the fifth example, that is, a synchronization control example (part 2) in the case of pixel arrangement in which the ON pixels 20a and the OFF pixels 20b are mixed in the pixel array unit 101. FIG. 28 illustrates a flowchart of synchronization control processing according to the seventh example.

First, the sensor control unit 1021 globally resets all pixels including the ON pixel 20a and the OFF pixel 20b (Step S221). Next, the light source drive unit 1011 irradiates the subject with light of a predetermined pattern from the laser light source 1010 which is a light source unit (Step S222). Next, the sensor control unit 1021 stores the on-event information On detected by the ON pixel 20a in the memory (Step S223). Here, the memory for storing the on-event information On is a gate parasitic capacitance of the on-event output transistor NM₂ in the output circuit 217.

Next, the sensor control unit 1021 sequentially transfers the on-event information On stored in the gate parasitic capacitance of the on-event output transistor NM₂ in the output circuit 217 to the readout circuit 130 (Step S224), and then, turns on the reset switch SW_{RS} of the OFF pixel 20b (Step S225).

Next, the light source drive unit 1011 ends the irradiation of the subject with light (Step S226). Next, the sensor control unit 1021 stores the off-event information Off detected by the OFF pixel 20b in the memory (Step S227). Here, the memory for storing the off-event information Off is a gate parasitic capacitance of the off-event output transistor NM₁ in the output circuit 217.

Thereafter, the sensor control unit 1021 sequentially transfers the on-event information On and the off-event information Off to the readout circuit 130 (Step S228), and then globally resets the voltage V_{diff}, which is the inverting input of the comparator 214, for the pixel for which the event detection has been performed (Step S229).

Thereafter, the system control unit 1050 determines whether or not to end the present operation (Step S230). In a case where the present operation ends (YES in Step S230), the system control unit ends a series of processing for synchronization control. In a case where the present operation does not end (NO in Step S230), the system control unit returns to Step S222, and executes subsequent operations.

1.14 Working and Effect

As described above, according to the first embodiment, since it is possible to acquire a plurality of pieces of sensor information of the RGB image acquired by the RGB pixel 10 and the EVS image acquired by the EVS pixel 20, it is possible to improve the accuracy of recognition processing using these pieces of sensor information. For example, as described above, by acquiring EVS image data in addition to RGB image data, it is possible to more accurately determine unauthorized access such as impersonation using a photograph in face authentication. Accordingly, it is possible to realize a solid-state imaging device and a recognition system that enable more secure authentication.

Furthermore, in the present embodiment, it is also possible to further improve the accuracy of the recognition processing by executing multi-stage recognition processing using a plurality of pieces of sensor information. As a result, it is possible to realize a solid-state imaging device and a recognition system that enable more secure authentication.

### 2. Second Embodiment

Next, a second embodiment will be described in detail with reference to the drawings. Note that, in the following description, the same configurations as those of the above-described embodiment are cited, and redundant description is omitted.

In the first embodiment described above, a case where one EVS pixel 20 is associated with one RGB pixel 10 has been described as an example. On the other hand, in the second embodiment, a case where a plurality of RGB pixels 10 is associated with one EVS pixel 20 will be described as an example.

2.1 Configuration Example of Unit Pixel

First, a configuration example of a unit pixel 110A according to the present embodiment will be described. Note that, here, as in the first embodiment, a case where the unit pixel 110A includes RGB pixels for acquiring an RGB image of three primary colors of RGB and an EVS pixel for acquiring an EVS image of infrared (IR) light will be described as an example. Furthermore, the RGB pixels 10 are arranged according to, for example, the Bayer array.

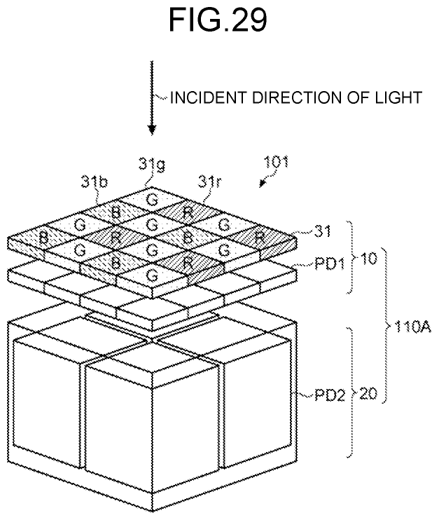

FIG. 29 is a schematic diagram illustrating a schematic configuration example of a unit pixel according to the second embodiment. As illustrated in FIG. 29, the unit pixel 110A has a structure in which one EVS pixel 20 is arranged in the light incident direction with respect to four RGB pixels 10 arranged in two rows and two columns. That is, in the present embodiment, one EVS pixel 20 is positioned in the direction perpendicular to the arrangement direction (planar direction) of the unit pixel 110A for the four RGB pixels 10, and the light transmitted through the four RGB pixels 10 positioned on the upstream side in the optical path of the incident light is configured to be incident on one EVS pixel 20 positioned on the downstream side of the four RGB pixels 10. Therefore, in the present embodiment, the optical axes of the incident light of the unit array of the Bayer array including the four RGB pixels 10 and the EVS pixel 20 coincide or substantially coincide with each other.

2.2 Example of Circuit Configuration of Unit Pixel

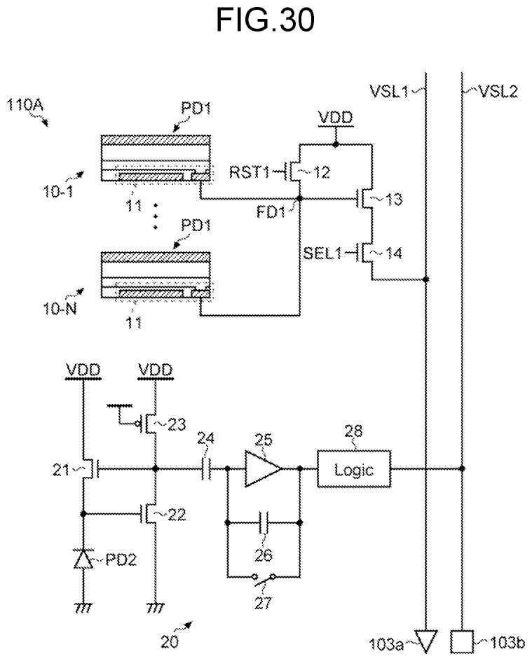

FIG. 30 is a circuit diagram illustrating a schematic configuration example of a unit pixel according to the second embodiment. Note that FIG. 30 is based on the unit pixel 110 according to the second modification described in the first embodiment with reference to FIG. 6, but is not limited thereto, and may be based on an unit pixel 110-3 illustrated in FIG. 7.

As illustrated in FIG. 30, the unit pixel 110A includes a plurality of RGB pixels 10-1 to 10-N (In FIG. 30, N is 4.) and one EVS pixel 20. As described above, in a case where one unit pixel 110A includes the plurality of RGB pixels 10, one pixel circuit (reset transistor 12, floating diffusion region FD, amplification transistor 13, and selection transistor 14) can be shared by the plurality of RGB pixels 10 (pixel sharing). Therefore, in the present embodiment, the plurality of RGB pixels 10-1 to 10-N share a pixel circuit including the reset transistor 12, the floating diffusion region FD, the amplification transistor 13, and the selection transistor 14. That is, in the present embodiment, a plurality of the photoelectric conversion units PD1 and the transfer gate 11 are connected to the common floating diffusion region FD.

2.3 Cross-sectional Structure Example of Unit Pixel

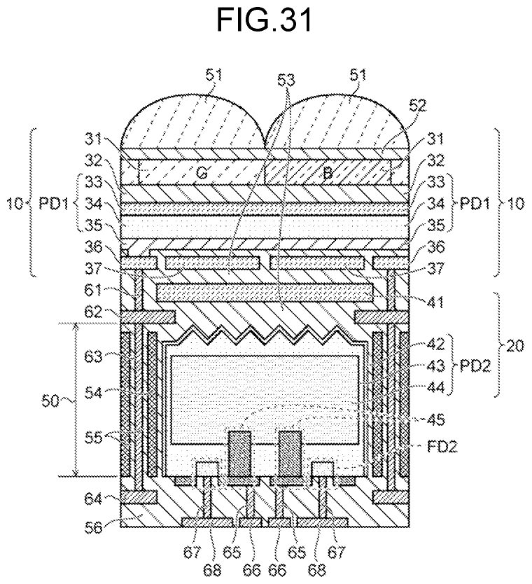

FIG. 31 is a cross-sectional view illustrating a cross-sectional structure example of the image sensor according to the second embodiment. Note that, in the present description, a case where each unit pixel 110A includes the four RGB pixels 10 arranged in two rows and two columns and one EVS pixel 20 will be described as an example, similarly to FIG. 29. Furthermore, in the following description, an example of a cross-sectional structure thereof will be described focusing on a semiconductor chip in which the photoelectric conversion units PD1 and PD2 are formed in the unit pixel 110A, similarly to FIG. 8. Moreover, in the following description, structures similar to the cross-sectional structure of the image sensor 100 described with reference to FIG. 8 in the first embodiment are cited, and redundant description is omitted.

As illustrated in FIG. 31, in the present embodiment, in a cross-sectional structure similar to the cross-sectional structure illustrated in FIG. 8, the on-chip lens 51, the color filter 31, and the storage electrode 37 are divided into four in two rows and two columns (However, two out of the four are illustrated in FIG. 31.), thereby configuring the four RGB pixels 10. Note that the four RGB pixels 10 in each unit pixel 110A may constitute a basic array of the Bayer array.

2.4 Planar Structure Example

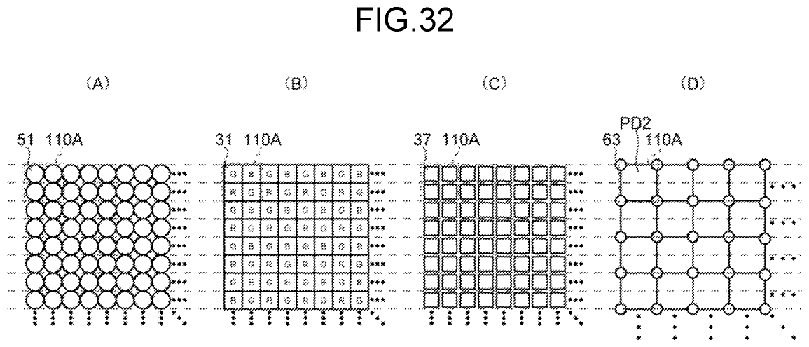

FIG. 32 is a diagram illustrating a planar layout example of each layer of the pixel array unit according to the second embodiment, in which (A) illustrates a planar layout example of the on-chip lens 51, (B) illustrates a planar layout example of the color filter 31, (C) illustrates a planar layout example of the storage electrode 37, and (D) illustrates a planar layout example of the photoelectric conversion unit PD2. Note that, in FIG. 32, (A) to (D) illustrate planar layout examples of surfaces parallel to the element formation surface of the semiconductor substrate 50.

As illustrated in (A) to (D) of FIG. 32, in the present embodiment, four on-chip lenses 51, four color filters 31, four storage electrodes 37, and one photoelectric conversion unit PD2 are provided for one unit pixel 110A. Note that, in the present description, one storage electrode 37 corresponds to one RGB pixel 10, and one photoelectric conversion unit PD2 corresponds to one EVS pixel 20.

As described above, in one unit pixel 110, by arranging the basic array of the Bayer array including the four RGB pixels 10 and one EVS pixel 20 along the traveling direction of the incident light, it is possible to improve the coaxiality with respect to the incident light between each of the RGB pixels 10 and the EVS pixel 20, and thus, it is possible to suppress the spatial deviation occurring between the RGB image and the EVS image. Accordingly, it is possible to improve the accuracy of the results obtained by integrally processing the information (the RGB image and the EVS image) acquired by the different sensors.

2.5 Modification Example of On-chip Lens

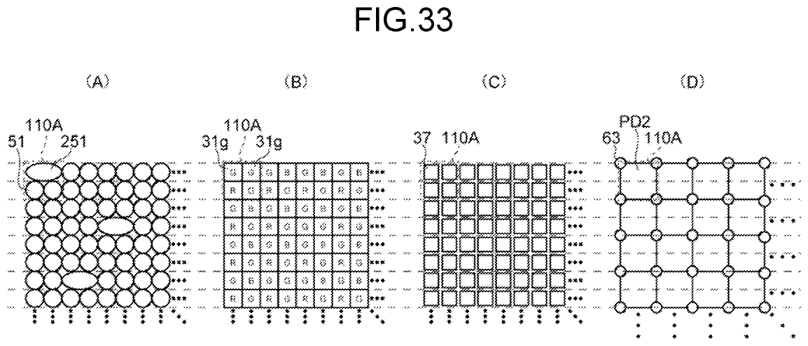

In the second embodiment described above, the case where one on-chip lens 51 is provided for one RGB pixel 10 has been exemplified, but the present invention is not limited thereto, and one on-chip lens may be provided for a plurality of the RGB pixels 10. FIG. 33 is a diagram illustrating a planar layout example of each layer of a pixel array unit according to a modification example of the on-chip lens of the second embodiment, and similarly to FIG. 32, (A) illustrates a planar layout example of the on-chip lens 51, (B) illustrates a planar layout example of the color filter 31, (C) illustrates a planar layout example of the storage electrode 37, and (D) illustrates a planar layout example of the photoelectric conversion unit PD2.

In the modification example of the on-chip lens illustrated in FIG. 33, as illustrated in (A), the two on-chip lenses 51 arrayed in the row direction in some of the unit pixels 110A among the plurality of unit pixels 110A are replaced with one on-chip lens 251 of 2×1 pixels straddling the two RGB pixels 10. Furthermore, as illustrated in (B) of FIG. 33, in the two RGB pixels 10 sharing the on-chip lens 251, the color filters 31 that selectively transmit the same wavelength component are provided. In the example illustrated in (B) of FIG. 33, in the upper left unit pixel 110A, the color filter 31b that selectively transmits the blue (B) wavelength component originally in the Bayer array is replaced with the color filter 31g that selectively transmits the green (G) wavelength component, whereby the color filters 31 of the two RGB pixels 10 sharing the on-chip lens 251 are unified to the color filters 31g.

Note that, for the RGB pixels 10 in which the color filters 31 are replaced in this manner, the pixel values of the wavelength components to be originally detected according to the Bayer array may be interpolated from, for example, the pixel values of surrounding pixels. For this pixel interpolation, various methods such as linear interpolation may be used.

Furthermore, in the modification example of the on-chip lens, a case where the two on-chip lenses 51 arranged in the row direction are made common is exemplified, but the present invention is not limited thereto, and various modifications such as a configuration in which the two on-chip lenses 51 arranged in the column direction are made common, a configuration in which all of the four on-chip lenses 51 included in one unit pixel 110A are replaced with one on-chip lens, and the like can be made. In that case, the color filters 31 that selectively transmit the same wavelength component may be used as the color filters 31 of the RGB pixels 10 that share the on-chip lens.

Moreover, the sharing of the on-chip lens 51 between the adjacent RGB pixels 10 is not limited to the second embodiment, and can also be applied to the first embodiment.

2.6 Modification Example of Color Filter Array

Furthermore, in the above-described embodiment and the modification example thereof, the Bayer array has been exemplified as the filter array of the color filters 31, but the present invention is not limited thereto. For example, various filter arrays such as a 3×3 pixel color filter array adopted in an X-Trans (registered trademark) CMOS sensor, a 4×4 pixel quad Bayer array (also referred to as a quadra array), and a 4×4 pixel color filter array (also referred to as a white RGB array) in which a white RGB color filter is combined with a Bayer array may be used.

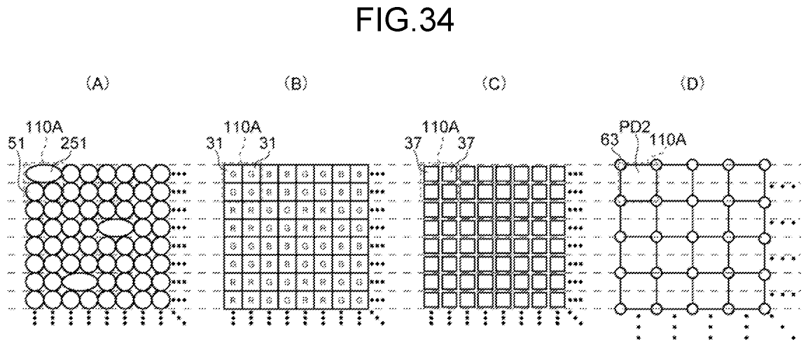

FIG. 34 is a diagram illustrating a planar layout example of each layer of a pixel array unit according to a modification example of the color filter array of the second embodiment, and similarly to FIGS. 32 and 33, (A) illustrates a planar layout example of the on-chip lens 51, (B) illustrates a planar layout example of the color filter 31, (C) illustrates a planar layout example of the storage electrode 37, and (D) illustrates a planar layout example of the photoelectric conversion unit PD2.

In the modification example of the color filter array illustrated in FIG. 34, as illustrated in (B), a quadra array of 4×4 pixels in total in which each color filter 31 in the Bayer array of 2×2 pixels is divided into 2×2 pixels is illustrated as the color filter array. In such a quadra array, as illustrated in (A) of FIG. 34, even in a case where the on-chip lens 51 is shared by two adjacent RGB pixels 10, since the color filters 31 in these RGB pixels 10 are originally aligned as illustrated in (B), it is not necessary to change the array of the color filters 31, and thus, there is no need to perform pixel interpolation.

2.7 Working and Effect

As described above, according to the second embodiment, the four photoelectric conversion units PD1 of the four RGB pixels 10 and one photoelectric conversion unit PD2 of one EVS pixel 20 are arranged in the light incident direction. Even in such a configuration, similarly to the first embodiment, it is possible to acquire a plurality of pieces of sensor information of the RGB image EVS image, and thus, it is possible to improve the accuracy of recognition processing using these pieces of sensor information. Accordingly, it is possible to realize a solid-state imaging device and a recognition system that enable more secure authentication.

Furthermore, similarly to the first embodiment, by executing multi-stage recognition processing using a plurality of pieces of sensor information, accuracy of the recognition processing can be further improved, so that it is possible to realize a solid-state imaging device and a recognition system that enable more secure authentication.

Other configurations, operations, and effects may be similar to those of the above-described embodiment, and thus detailed description thereof is omitted here.

### 3. Specific Example of Electronic Device

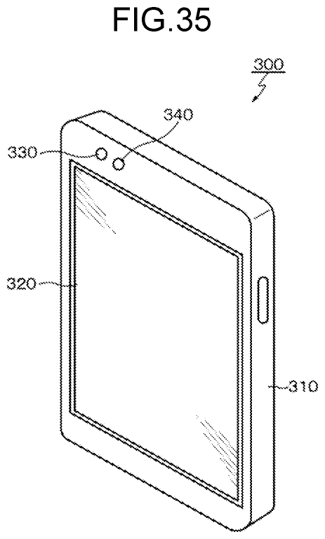

Here, a smartphone is exemplified as a specific example of an electronic device to which the recognition system of the present disclosure can be applied. FIG. 35 illustrates an external view of a smartphone according to a specific example of the electronic device of the present disclosure as viewed from the front side.

A smartphone 300 according to the present specific example includes a display unit 320 on a front side of a housing 310. Furthermore, the smartphone 300 includes a light emitting unit 330 and a light receiving unit 340 in an upper part on the front side of the housing 310. Note that an arrangement example of the light emitting unit 330 and the light receiving unit 340 illustrated in FIG. 35 is an example, and is not limited to this arrangement example.

In the smartphone 300 which is an example of the mobile device having the above-described configuration, the laser light source 1010 (VCSEL 1012) in the electronic device 1 according to the above-described embodiment can be used as the light emitting unit 330, and the image sensor 100 can be used as the light receiving unit 340. That is, the smartphone 300 according to the present specific example is manufactured by using the electronic device 1 according to the above-described embodiment as the three-dimensional image acquisition system.

The electronic device 1 according to the above-described embodiment can increase the resolution of a range image without increasing the number of light sources in the array dot arrangement of the light sources. Therefore, the smartphone 300 according to the present specific example can have a highly accurate face recognition function (face authentication function) by using the electronic device 1 according to the above-described embodiment as the three-dimensional image acquisition system (face authentication system).

### 4. Application Example to Mobile Body

The technique according to the present disclosure can be further applied to various products. For example, the technique according to the present disclosure may be realized as a device mounted on any type of mobile body such as an automobile, an electric vehicle, a hybrid electric vehicle, a motorcycle, a bicycle, a personal mobility, an airplane, a drone, a ship, and a robot.

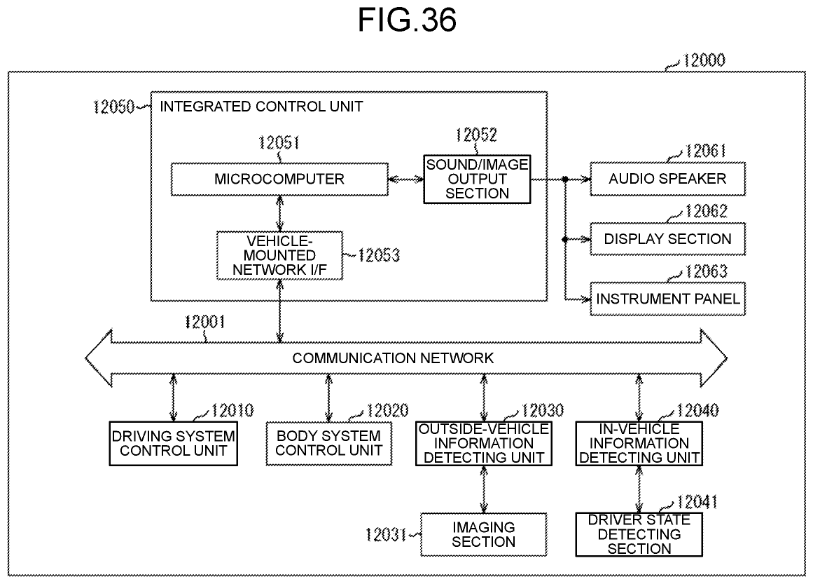

FIG. 36 is a block diagram depicting an example of schematic configuration of a vehicle control system as an example of a mobile body control system to which the technology according to an embodiment of the present disclosure can be applied.

A vehicle control system 12000 includes a plurality of electronic control units connected to each other via a communication network 12001. In the example depicted in FIG. 36, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 36, an audio speaker 12061, a display section 12062, and an instrument panel 12063 are illustrated as the output device. The display section 12062 may, for example, include at least one of an on-board display and a head-up display.

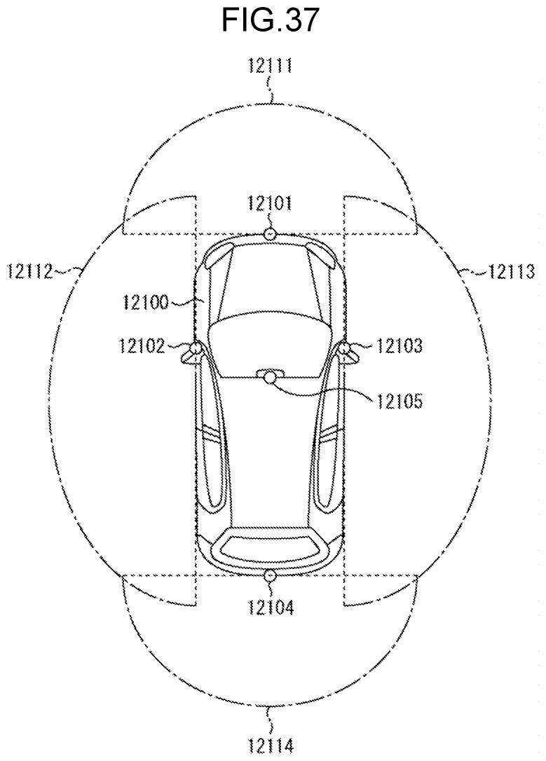

FIG. 37 is a diagram depicting an example of the installation position of the imaging section 12031.

In FIG. 37, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of a vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 37 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained with respect to a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technique according to the present disclosure can be applied has been described above. The technique according to the present disclosure can be applied to the imaging section 12031 and the like among the configurations described above. Specifically, the imaging sections 12101, 12102, 12103, 12104, 12105, and the like illustrated in FIG. 37 may be mounted on the vehicle 12100. By applying the technique according to the present disclosure to the imaging sections 12101, 12102, 12103, 12104, 12105, and the like, it is possible to improve the accuracy of results obtained by integrally processing information (for example, a color image and a monochrome image) acquired by different sensors.

Although the embodiments of the present disclosure have been described above, the technical scope of the present disclosure is not limited to the above-described embodiments as it is, and various modifications can be made without departing from the gist of the present disclosure. Furthermore, components of different embodiments and modification examples may be appropriately combined.

Furthermore, the effects of each embodiment described in the present specification are merely examples and are not limited, and other effects may be provided.

Note that the present technique can also have the following configurations.

(1)

A solid-state imaging device including:
an image processing unit including a plurality of first pixels arranged in a matrix on a first surface, the image processing unit generating image data based on a light amount of incident light incident on each of the first pixels; and
an event signal processing unit including a plurality of second pixels arranged in a matrix on a second surface parallel to the first surface, the event signal processing unit generating event data based on a luminance change of incident light incident on each of the second pixels,
wherein the plurality of first pixels and the plurality of second pixels are arranged on a single chip.
   (2)

The solid-state imaging device according to (1), wherein the plurality of first pixels include an organic photoelectric conversion film.

(3)

The solid-state imaging device according to (1) or (2), wherein at least a part of the plurality of first pixels overlaps the plurality of second pixels in a first direction.

(4)

The solid-state imaging device according to (3), wherein the first direction is a direction perpendicular to a plane on which the first pixels are arranged.

(5)

The solid-state imaging device according to any one of (1) to (4), wherein
each of the first pixels includes a first photoelectric conversion unit that photoelectrically converts the incident light,
each of the second pixels includes a second photoelectric conversion unit that photoelectrically converts the incident light, and
the second photoelectric conversion unit is disposed on a surface side opposite to an incident surface of the incident light in the first photoelectric conversion unit.
   (6)

The solid-state imaging device according to any one of (1) to (5), including:
a first chip including the first pixels and the second pixels; and
a second chip including a driving unit that drives the first pixels and the second pixels, and a reading unit that reads a pixel signal from the first pixels and the second pixels,
wherein the first chip and the second chip are bonded to each other to constitute the single chip including a laminated structure.
   (7)

The solid-state imaging device according to any one of (1) to (6), wherein
the image processing unit generates the image data based on a light amount of light of two or more wavelength components, and
the event signal processing unit generates the event data indicating a position of a second pixel in which luminance of the incident light has changed.
   (8)

The solid-state imaging device according to any one of (1) to (7), wherein
each of the first pixels detects the light amount of visible light included in the incident light, and
each of the second pixels detects a luminance change of infrared light included in the incident light.
   (9)

The solid-state imaging device according to any one of (1) to (8), wherein
each of the second pixels detects at least one of a state where the luminance of the incident light exceeds a predetermined threshold and a state where the luminance of the incident light falls below a predetermined threshold.
   (10)

The solid-state imaging device according to any one of (1) to (8), wherein
at least one of the plurality of second pixels detects that the luminance of the incident light exceeds a predetermined threshold, and another one of the plurality of second pixels detects that the luminance of the incident light falls below a predetermined threshold.
   (11)

The solid-state imaging device according to any one of (1) to (10), wherein
the event signal processing unit includes a plurality of the first pixels for one of the second pixels in the image processing unit.
   (12)

A recognition system including:
the solid-state imaging device according to any one of (1) to (11); and
a recognition processing unit that executes recognition processing based on the image data acquired by the image processing unit in the solid-state imaging device and the event data acquired by the event signal processing unit.
   (13)

The recognition system according to (12), further including:
a light source that emits light of a predetermined wavelength band; and
a control unit that controls the light source and the solid-state imaging device,
wherein each of the second pixels includes a wavelength selection filter that selectively transmits light of the predetermined wavelength band,
the event signal processing unit generates the event data based on the luminance change of light of the predetermined wavelength band in the incident light, and
the control unit performs control to synchronize a light emission timing of the light source with a drive timing of the event signal processing unit in the solid-state imaging device.
   (14)

The recognition system according to (12) or (13), wherein
the recognition processing unit executes:
first recognition processing based on one of the image data and the event data; and
second recognition processing based on a result of the first recognition processing and another one of the image data and the event data.

### REFERENCE SIGNS LIST

10, 10-1 to 10-N RGB PIXEL

11 TRANSFER GATE

12 RESET TRANSISTOR

13 AMPLIFICATION TRANSISTOR

14 SELECTION TRANSISTOR

20 EVS PIXEL

20a ON PIXEL

20b OFF PIXEL

31, 31r, 31g, 31b COLOR FILTER

32 SEALING FILM

33 TRANSPARENT ELECTRODE

34 PHOTOELECTRIC CONVERSION FILM

35 SEMICONDUCTOR LAYER

36 READ ELECTRODE

37 STORAGE ELECTRODE

41 IR FILTER

42 p-WELL REGION

43 p-TYPE SEMICONDUCTOR REGION

44 n-TYPE SEMICONDUCTOR REGION

45 VERTICAL TRANSISTOR

51 ON-CHIP LENS

52 FLATTENING FILM

53 INSULATING LAYER

54 PIXEL SEPARATION UNIT

55 FIXED CHARGE FILM

56 INTERLAYER INSULATING FILM

61 to 66 WIRING

100 IMAGE SENSOR

101 PIXEL ARRAY UNIT

102A VERTICAL DRIVE CIRCUIT

102B HORIZONTAL DRIVE CIRCUIT

103A RGB SIGNAL PROCESSING CIRCUIT

103a AC CONVERSION CIRCUIT

103B EVS SIGNAL PROCESSING CIRCUIT

103b SIGNAL PROCESSING UNIT

104A X ARBITER

104B Y ARBITER

105 SYSTEM CONTROL CIRCUIT

108A RGB DATA PROCESSING UNIT

108B EVS DATA PROCESSING UNIT

110 UNIT PIXEL

131, 132 SWITCH CIRCUIT

140 PIXEL CHIP

150 CIRCUIT CHIP

210 ADDRESS EVENT DETECTION CIRCUIT

212 LIGHT RECEIVING CIRCUIT

213 MEMORY CAPACITY

214, 214A, 214B COMPARATOR

215 RESET CIRCUIT

216 INVERTER

217 OUTPUT CIRCUIT

2151 2 INPUT OR CIRCUIT

2152 2 INPUT AND CIRCUIT

300 SMARTPHONE

310 HOUSING

320 DISPLAY UNIT

330 LIGHT EMITTING UNIT

340 LIGHT RECEIVING UNIT

901 SUBJECT

1000 RECOGNITION SYSTEM

1001 RGB SENSOR UNIT

1002 RGB IMAGE PROCESSING UNIT

1003 EVS SENSOR UNIT

1004 EVENT SIGNAL PROCESSING UNIT

1005 RECOGNITION PROCESSING UNIT

1006 INTERFACE UNIT

1010 LASER LIGHT SOURCE

1011 LIGHT SOURCE DRIVE UNIT

1012 VCSEL

1021 SENSOR CONTROL UNIT

1022 LIGHT RECEIVING UNIT

1030 IRRADIATION LENS

1040 IMAGING LENS

1050 SYSTEM CONTROL UNIT

1100 APPLICATION PROCESSOR

LD1, LD2 PIXEL DRIVE LINE

NM₁ OFF-EVENT OUTPUT TRANSISTOR

NM₂ ON-EVENT OUTPUT TRANSISTOR

NM₃ CURRENT SOURCE TRANSISTOR

PD1, PD2 PHOTOELECTRIC CONVERSION UNIT

SW_{RS} RESET SWITCH

SW_{ON}, SW_{OFF} SELECTION SWITCH

VSL, VSL1, VSL2 VERTICAL SIGNAL LINE

What is claimed is:

1. A solid-state imaging device, including:
an image processing unit including a plurality of first pixels arranged in a matrix on a first surface, the image processing unit generating image data based on a light amount of incident light incident on each of the first pixels; and
an event signal processing unit including a plurality of second pixels arranged in a matrix on a second surface parallel to the first surface, the event signal processing unit generating event data based on a luminance change of incident light incident on each of the second pixels,
wherein the plurality of first pixels and the plurality of second pixels are arranged on a single chip.

2. The solid-state imaging device according to claim 1, wherein the plurality of first pixels include an organic photoelectric conversion film.

3. The solid-state imaging device according to claim 1, wherein at least a part of the plurality of first pixels overlaps the plurality of second pixels in a first direction.

4. The solid-state imaging device according to claim 3, wherein the first direction is a direction perpendicular to a plane on which the first pixels are arranged.

5. The solid-state imaging device according to claim 1, wherein
each of the first pixels includes a first photoelectric conversion unit that photoelectrically converts the incident light,
each of the second pixels includes a second photoelectric conversion unit that photoelectrically converts the incident light, and
the second photoelectric conversion unit is disposed on a surface side opposite to an incident surface of the incident light in the first photoelectric conversion unit.

6. The solid-state imaging device according to claim 1, including:
a first chip including the first pixels and the second pixels; and
a second chip including a driving unit that drives the first pixels and the second pixels, and a reading unit that reads a pixel signal from the first pixels and the second pixels,
wherein the first chip and the second chip are bonded to each other to constitute the single chip including a laminated structure.

7. The solid-state imaging device according to claim 1, wherein
the image processing unit generates the image data based on a light amount of light of two or more wavelength components, and
the event signal processing unit generates the event data indicating a position of a second pixel in which luminance of the incident light has changed.

8. The solid-state imaging device according to claim 1, wherein
each of the first pixels detects the light amount of visible light included in the incident light, and
each of the second pixels detects a luminance change of infrared light included in the incident light.

9. The solid-state imaging device according to claim 1, wherein
each of the second pixels detects at least one of a state where the luminance of the incident light exceeds a predetermined threshold and a state where the luminance of the incident light falls below a predetermined threshold.

10. The solid-state imaging device according to claim 1, wherein
at least one of the plurality of second pixels detects that the luminance of the incident light exceeds a predetermined threshold, and another one of the plurality of second pixels detects that the luminance of the incident light falls below a predetermined threshold.

11. The solid-state imaging device according to claim 1, wherein
the event signal processing unit includes a plurality of the first pixels for one of the second pixels in the image processing unit.

12. A recognition system including:
the solid-state imaging device according to claim 1; and
a recognition processing unit that executes recognition processing based on the image data acquired by the image processing unit in the solid-state imaging device and the event data acquired by the event signal processing unit.

13. The recognition system according to claim 12, further including:
a light source that emits light of a predetermined wavelength band; and
a control unit that controls the light source and the solid-state imaging device,
wherein each of the second pixels includes a wavelength selection filter that selectively transmits light of the predetermined wavelength band,
the event signal processing unit generates the event data based on the luminance change of light of the predetermined wavelength band in the incident light, and
the control unit performs control to synchronize a light emission timing of the light source with a drive timing of the event signal processing unit in the solid-state imaging device.

14. The recognition system according to claim 12, wherein
the recognition processing unit executes:
first recognition processing based on one of the image data and the event data; and
second recognition processing based on a result of the first recognition processing and another one of the image data and the event data.
